(19) United States
(12) Patent Application Publication
(10) Pub. No.: US 2025/0357254 A1
(43) Pub. Date: Nov. 20, 2025

(54) SEMICONDUCTOR PACKAGE

(71) Applicant: Samsung Electronics Co., Ltd., Suwon-si (KR)

(72) Inventor: Gitae Park, Suwon-si (KR)

(21) Appl. No.: 19/050,456

(22) Filed: Feb. 11, 2025

(30) Foreign Application Priority Data
May 16, 2024 (KR) 10-2024-0063835

(51) Int. Cl. H01L 23/373; H01L 23/00; H01L 23/13; H01L 23/31; H01L 23/538; H01L 25/00; H01L 25/18

(52) U.S. Cl. CPC H01L 23/3735; H01L 23/13; H01L 23/5385; H01L 23/5386; H01L 24/32; H01L 25/18; H01L 23/3107; H01L 24/16; H01L 24/73; H01L 25/50; H01L 2224/16227; H01L 2224/32225; H01L 2224/73204; H01L 2224/73253

(57) ABSTRACT

A semiconductor package may include a package substrate; a first semiconductor device on the package substrate; a plurality of vertical conductive connectors on the package substrate; an interposer on the package substrate such that the plurality of vertical conductive connectors is between the package substrate and the interposer, the interposer defining a first interposer region and a second interposer region and having a lower cavity in the first interposer region, the lower cavity having a predetermined depth from a lower surface of the interposer; a second semiconductor device on the second interposer region; and a heat dissipation block on the first interposer region, wherein a portion of the first semiconductor device is within the lower cavity.

### CROSS-REFERENCE TO RELATED APPLICATION

This application claims priority under 35 U.S.C. § 119 to Korean Patent Application No. 10-2024-0063835, filed on May 16, 2024, in the Korean Intellectual Property Office (KIPO), the contents of which are herein incorporated by reference in their entirety.

### FIELD

Some embodiments relate to a semiconductor package including a first package and a second package stacked on the first package. More particularly, some embodiments relate to a semiconductor package including a first semiconductor package, a second semiconductor package, and an interposer connecting the first semiconductor package and the second semiconductor package.

### BACKGROUND

In an interposer-package on package (I-POP) structure, where one semiconductor package is mounted on another semiconductor package through an interposer, a heat path block (HPB) may be applied for heat dissipation of an application processor (AP) chip. In this case, to enhance thermal performance of a semiconductor package, it is necessary to reduce a distance between the heat path block (HPB) and the application processor (AP) chip.

### SUMMARY

Some embodiments provide a semiconductor package capable of improving thermal performance.

According to some embodiments, a semiconductor package includes a package substrate; a first semiconductor device on the package substrate; a plurality of vertical conductive connectors on the package substrate and electrically connected to the first semiconductor device; an interposer on the package substrate such that the plurality of vertical conductive connectors is between the package substrate and the interposer, the interposer defining a first interposer region and a second interposer region and having a lower cavity in the first interposer region, the lower cavity having a predetermined depth from a lower surface of the interposer; a second semiconductor device on the interposer in the second interposer region; and a heat dissipation block on the interposer in the first interposer region, wherein a portion of the first semiconductor device is within the lower cavity.

According to some embodiments, a semiconductor package includes a package substrate further including a mounting region and a connecting region spaced apart from the mounting region along a horizontal direction; a first semiconductor device mounted on the mounting region of the package substrate; a plurality of vertical conductive connectors on the connecting region of the package substrate; an interposer on the package substrate such that the plurality of vertical conductive connectors is between the package substrate and the interposer, the interposer further including a first interposer region overlapped with the first semiconductor device and a second interposer region adjacent to the first interposer region; a second semiconductor device on the second interposer region; and a heat dissipation block on the first interposer region of the interposer, wherein the interposer includes a lower cavity on the first interposer region of the interposer having a predetermined depth from a lower surface of the interposer, wherein a portion of the first semiconductor device is in the lower cavity; and an upper cavity on the first interposer region of the interposer having a predetermined depth from an upper surface of the interposer, wherein a portion of the heat dissipation block is in the upper cavity.

According to some embodiments, a semiconductor package includes a package substrate further including a mounting region and a connecting region spaced apart from the mounting region along a horizontal direction; a first semiconductor device mounted on the mounting region of the package substrate; a plurality of vertical conductive connectors on the connecting region of the package substrate; an interposer on the package substrate such that the plurality of vertical conductive connectors is between the package substrate and the interposer, the interposer further including a first interposer region overlapped with the first semiconductor device and a second interposer region adjacent to the first interposer region; a molding member between the package substrate and the interposer to cover the plurality of vertical conductive connectors and the first semiconductor device; a second semiconductor device on the second interposer region of the interposer; and a heat dissipation block on the first interposer region of the interposer, wherein the interposer includes a lower cavity on the first interposer region of the interposer having a predetermined depth from a lower surface of the interposer, wherein a portion of the first semiconductor device is in the lower cavity; and an upper cavity on the first interposer region of the interposer having a predetermined depth from an upper surface of the interposer, wherein a portion of the heat dissipation block is in the upper cavity.

According to some embodiments, a semiconductor package may include a package substrate, a first semiconductor device on the package substrate, a plurality of vertical conductive connectors on the package substrate, an interposer on the package substrate such that the plurality of vertical conductive connectors is between the package substrate and the interposer, a heat dissipation block stacked on the interposer, and a second semiconductor device on the interposer and spaced apart from the heat dissipation block.

The interposer may include a lower cavity having a predetermined depth from a lower surface of the interposer to accommodate a portion of the first semiconductor device and an upper cavity having a predetermined depth from an upper surface of the interposer to accommodate a portion of the heat dissipation block. The interposer may further include a plurality of heat transfer vias connecting the lower cavity and the upper cavity.

Accordingly, the lower cavity and the upper cavity may reduce a distance between the first semiconductor device and the heat dissipation block, thereby improving a thermal performance of the semiconductor package. Additionally, the lower cavity may allow for an increase in a thickness of the first semiconductor device, further enhancing the thermal performance of the semiconductor package. Furthermore, the plurality of heat transfer vias may rapidly facilitate heat transfer between the first semiconductor device and the heat dissipation block, thereby improving the thermal performance of the semiconductor package.

### BRIEF DESCRIPTION OF THE DRAWINGS

FIG. 1 is a cross-sectional view illustrating a semiconductor package according to some embodiments.

FIGS. 2 to 28 are views illustrating a method of manufacturing a semiconductor package according to some embodiments.

FIG. 29 is a cross-sectional view illustrating a semiconductor package according to some embodiments.

FIGS. 30 to 34 are views illustrating a method of manufacturing a semiconductor package according to some embodiments.

FIG. 35 is a cross-sectional view illustrating a semiconductor package according to some embodiments.

FIGS. 36 and 37 are views illustrating a method of manufacturing a semiconductor package according to some embodiments.

FIG. 38 is a cross-sectional view illustrating a semiconductor package according to some embodiments.

FIG. 39 is a cross-sectional view illustrating a semiconductor package according to some embodiments.

FIG. 40 is a cross-sectional view illustrating a semiconductor package according to some embodiments.

FIGS. 41 and 42 are views illustrating a method of manufacturing a semiconductor package according to some embodiments.

FIG. 43 is a cross-sectional view illustrating a semiconductor package according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. The term “and/or” includes any and all combinations of one or more of the associated listed items. The term “connected” may be used herein to refer to a physical and/or electrical connection.

Further, throughout the specification, the phrase “in a plan view” means when an object portion is viewed from above, and the phrase “in a cross-sectional view” means when a cross-section taken by vertically cutting an object portion is viewed from the side.

Herein the terms “front surface” and “backside surface” may be used with respect to the surfaces of various components. It should be understood that unless otherwise specified, “backside surface” describes the surface which is visible when the component is viewed in plan view. Similarly, the “front surface” describes a surface of a component which is substantially parallel to the backside surface but is on the opposite side of the component from the backside surface.

Hereinafter, some embodiments will be explained in detail with reference to the accompanying drawings.

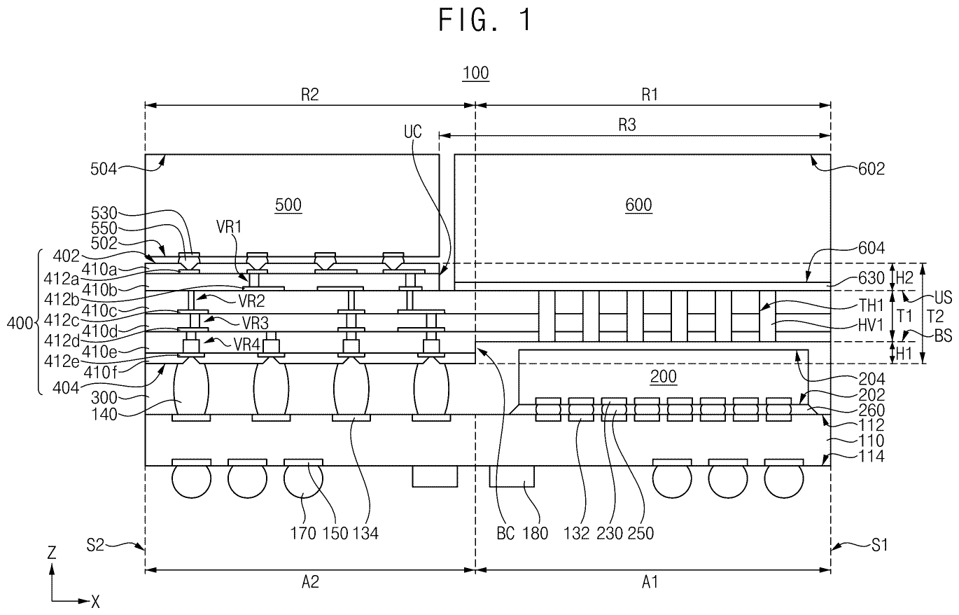

FIG. 1 is a cross-sectional view illustrating a semiconductor package in accordance with some embodiments.

Referring to FIG. 1, a semiconductor package 100 may include may include a package substrate 110, and a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 along a first direction (X direction).

For example, the semiconductor package may be a package-on-package (POP) structure where a first package is mounted on a second package. Particularly, the semiconductor package may be an interposer package-on-package including an interposer.

In some embodiments, the package substrate 110 may provide an upper surface 112 and a lower surface 114 facing each other. The package substrate 110 may include a plurality of upper substrate pads 130 on the upper surface 112 and a plurality of lower substrate pads 150 on the lower surface 114. Additionally, the package substrate 110 may further include a plurality of external connection members 170 respectively provided on the plurality of lower substrate pads 150 and a plurality of passive components 180 provided on the lower surface 114. In some embodiments, each of the plurality of external connection members 170 may be on a different one of the plurality of lower substrate pads 150. For example, the plurality of upper substrate pads 130, the plurality of lower substrate pads 150, and the plurality of external connection members 170 may respectively include a conductive metallic material. Additionally, the plurality of passive components 180 may include a capacitor configured to improve electrical characteristics of the package substrate 110.

The package substrate 110 may provide a first side portion S1 and a second side portion S2 facing each other. The upper surface 112 of the package substrate 110 may include a first substrate region A1 adjacent to the first side portion S1 and a second substrate region A2 adjacent to the second side portion S2. For example, the first substrate region A1 may include a mounting region where a first semiconductor device 200, which will be described later, is mounted. Additionally, the second substrate region A2 may include a connection region electrically connecting the interposer 400 to the package substrate 110.

The plurality of upper substrate pads 130 may include a plurality of first upper substrate pads 132 provided within the first substrate region A1 and a plurality of second upper substrate pads 134 provided within the second substrate region A2.

The package substrate 110 may further include a plurality of vertical conductive connectors 140 respectively provided on the plurality of second upper substrate pads 134 and electrically connected to the plurality of second upper substrate pads 134 respectively. In some embodiments, each of the plurality of vertical conductive connectors 140 may be on and electrically connected to a different one of the plurality of second upper substrate pads 134. For example, the plurality of vertical conductive connectors 140 may each include a conductive metallic material.

In some embodiments, the first semiconductor device 200 may have a front surface 202 and a backside surface 204 that face each other. In other words, the front surface 202 and the backside surface 204 may be directly opposite of one another. The first semiconductor device 200 may be mounted on the first substrate region A1 of the package substrate 110 such that the front surface 202 faces the package substrate 110. For example, the first semiconductor device 200 may be a processor chip such as an ASIC, an application processor (AP) as a host, such as CPU, GPU, SOC, etc. The front surface 202 may be an active surface on which electronic elements such as transistors are formed. The backside surface 204 may be an inactive surface.

The first semiconductor device 200 may include a plurality of first chip pads 230 provided on the front surface 202, a plurality of first conductive connection members 250 provided on the plurality of first chip pads 230 respectively, and an underfill member 260 provided on the front surface 202 to cover the plurality of first conductive connection members 250. For example, the plurality of first chip pads 230 and the plurality of first conductive connection members 250 may each include a conductive metallic material for electrical connection. Additionally, the underfill member 260 may include an adhesive including an epoxy material.

The first semiconductor device 200 may be mounted on the package substrate 110 with the plurality of first conductive connection members 250 provided between the plurality of first upper substrate pads 132 and the plurality of first chip pads 230, respectively.

In some embodiments, the molding member 300 may be provided on the upper surface 112 of the package substrate 110 to cover the plurality of vertical conductive connectors 140 and the first semiconductor device 200. For example, the molding member 300 may include an epoxy molding compound (EMC).

In some embodiments, the interposer 400 may include a plurality of insulation layers 410 and a plurality of internal wirings 412 in the plurality of insulation layers 410. The interposer 400 may include an upper surface 402 and a lower surface 404 that face each other. In other words, the upper surface 402 and the lower surface 404 may be directly opposite of one another. The interposer 400 may include a plurality of internal vias VR1, VR2, VR3, and VR4 electrically connecting the plurality of internal wiring 412.

The plurality of insulation layers 410 may include first to sixth insulation layers 410a, 410b, 410c, 410d, 410e, and 410f. The first insulation layer 410a may be an upper cover layer, and the sixth insulation layer 410f may be a lower cover layer. The first insulation layer 410a and the sixth insulation layer 410f may include a solder resist. For example, the first insulation layer 410a as an uppermost insulation layer may include the upper surface 402 of the interposer 400. The sixth insulation layer 410f as a lowest insulation layer may include the lower surface 404 of the interposer 400.

The plurality of internal wirings 412 may include first to fifth wires 412a, 412b, 412c, 412d, and 412e. The first wire 412a may be provided on the second insulation layer 410b, and the first wire 412a as an uppermost wire may by exposed from the first insulation layer 410b to serve as an upper pad. The second wire 412b may be provided on the third insulation layer 410c, the third wire 412c may be provided on the fourth insulation layer 410d, and the fourth wire 412d may be provided on the fifth insulation layer 410e. The fifth wire 412e may be provided on the fifth insulation layer 410e, and the fifth wire 412e as a lowermost wire may be exposed from the sixth insulation layer 410f to serve as a lower pad.

While figures illustrate that the interposer depict it as having six insulation layers and five wires, it will be understood that the present inventive concept is not limited thereto. Thus, the number, size, thickness, etc. of the insulation layers and the wires of the interposer may be varied.

The interposer 400 may be on the package substrate 110 such that the plurality of vertical conductive connectors 140 intervene (or is interposed) between the package substrate 110 and the interposer 400. For example, the interposer 400 may be on the package substrate 110 to be supported by the plurality of vertical conductive connectors 140 and the molding member 300.

The interposer 400 may include a first interposer region R1 provide on an upper portion of the first semiconductor device 200 and a second interposer region R2 adjacent to the first interposer region R1. For example, the second interposer region R2 may be a region surrounding the first interposer region R1. The plurality of internal wirings 412 may be located within the second interposer region R2 to be electrically connected to a plurality of vertical conductive connectors 140. The interposer 400 may include a third interposer region R3, which is at least partially overlapped with the first interposer region R1, on the upper surface 402.

The interposer 400 may include a lower cavity BC provided on the first interposer region R1 and having a first depth H1 from the lower surface 404 to accommodate at least a portion of the first semiconductor device 200 such that a portion of the first semiconductor device 200 is in the lower cavity BC, and the interposer 400 may include an upper cavity UC provided on the third interposer region R3 and having a second depth H2 from the upper surface 402. The lower cavity BC and the upper cavity UC may be receiving recesses configured to at least partially receive an element included in the package. For example, the recesses may be recesses having a square shape, when viewed in a plan view. Thus, a thickness of the first semiconductor device 200 may be enlarged by utilizing the first depth H1 of the lower cavity BC, thereby improving a thermal performance of the semiconductor package 100. For example, heat generated by the first semiconductor device 200 may be effectively dissipated.

The interposer 400 may include a plurality of first heat transfer vias HV1 provided between the lower cavity BC and the upper cavity UC, respectively. The plurality of first heat transfer vias HV1 may connect the lower cavity BC and the upper cavity UC, respectively. For example, the lower cavity BC may have a lower exposed surface BS exposing an interior facing the first semiconductor device 200, and the upper cavity UC may have an upper exposed surface US exposing an interior in a direction opposite to the lower cavity BC. The interposer 400 may have a plurality of first through holes TH1 connecting the lower exposed surface BS and the upper exposed surface US. The plurality of first heat transfer vias HV1 may be respectively provided within the plurality of first through holes TH1 to extend between the lower cavity BC and the upper cavity UC.

The interposer 400 may include a first portion in which the lower cavity BC and upper cavity UC are provided and a second portion in which the plurality of internal wirings 412 is provided. For example, the first portion may be provided on the molding member 300 to be located above the first semiconductor device 200. Further, the second portion may be provided on the plurality of vertical conductive connectors 140. The plurality of first heat transfer vias HV1 may be provided within the first portion.

The first portion may have a first thickness T1. For example, the first thickness of the first portion may be a distance from the upper exposed surface US to the lower exposed surface BS. The thickness of the second portion may have a second thickness T2 that is greater than the first thickness T1. For example, the second thickness of the second portion may be a distance from the upper surface 402 of the interposer 400 to the lower surface 404 of the interposer 400.

In some embodiments, the second semiconductor device 500 may have a front surface 502 and a backside surface 504 that face each other, and the second semiconductor device 500 may be mounted on the second interposer region R2 of the interposer 400 such that the front surface 502 faces the interposer 400. In other words, the front surface 502 and the backside surface 504 may be directly opposite of one another. For example, the second semiconductor device 500 may include a non-volatile memory device such as DRAM or NAND flash memory. The second semiconductor device 500 may be a package including a plurality of semiconductor chips.

The second semiconductor device 500 may include a plurality of second chip pads 530 provided on the front surface 502 and a plurality of second conductive connection members 550 respectively provided on the plurality of second chip pads 530. In some embodiments, each of the plurality of second conductive connection members 550 may be on a different one of the plurality of second chip pads 530. For example, the plurality of second chip pads 530 and the plurality of second conductive connection members 550 may each include a conductive metallic material for electrical connection.

The second semiconductor device 500 may be mounted on the second interposer region R2 of the interposer 400 with the plurality of second conductive connection members 550 respectively provided between the first wire 412a as the upper pad and the plurality of second chip pads 530.

In some embodiments, the heat dissipation block 600 may have an upper surface 604 and a lower surface 602 that face each other. In other words, the upper surface 604 and the lower surface 602 may be directly opposite of one another. The heat dissipation block 600 may include a first thermal adhesive member 630 provided on the lower surface 602. For example, the heat dissipation block 600 may be a heat path block (HPB) including a metallic material such as aluminum (Al) or copper (Cu). The heat path block (HPB) may be a structure to facilitate heat dissipation inside the semiconductor package 100 to outside for improving thermal performance. Further, the first thermal adhesive member 630 may include a thermal interface material (TIM). The thermal interface material (TIM) may be a structure for effectively transferring heat between components by closely fitting the components so that there are no microscopic spaces between the components.

The heat dissipation block 600 may be provided inside the upper cavity UC of the interposer 400 spaced apart from the second semiconductor device 500 in the first direction (X direction). For example, the interposer 400 may have the upper cavity UC in the third interposer region R3, the upper cavity UC having a second depth H2 from the upper surface 402 to accommodate at least a portion of the heat dissipation block 600 such that a portion of the heat dissipation block 600 is in the upper cavity UC. The heat dissipation block 600 may be stacked on the third interposer region R3 of the interposer 400 with a first thermal adhesive member 630 provided between the lower surface 602 of the heat dissipation block 600 and the upper exposed surface US of the upper cavity UC.

Thus, the semiconductor package 100 may reduce a distance between the first semiconductor device 200 and the heat dissipation block 600 by utilizing the lower cavity BC and upper cavity UC of the interposer 400.

As described above, the semiconductor package 100 may include a package substrate 110, a first semiconductor device 200 mounted on the package substrate 110, a molding member 300 provided on the package substrate 110 to cover the first semiconductor device 200, the interposer 400 provided on the molding member 300, the second semiconductor device 500 mounted on the interposer 400, and the heat dissipation block 600 stacked on the interposer 400 to be spaced apart from the second semiconductor device 500 in the first direction (X direction).

The interposer 400 may include the lower cavity BC to accommodate at least a portion of the first semiconductor device 200 and the upper cavity UC to accommodate at least a portion of the heat dissipation block 600. Further, the interposer 400 may include a plurality of first heat transfer vias HV1 provided between the lower cavity BC and the upper cavity UC.

Accordingly, the lower cavity BC and the upper cavity UC may reduce the distance between the first semiconductor device 200 and the heat dissipation block 600, thereby improving the thermal performance of the semiconductor package 100. Further, the lower cavity BC may allow an increase of the thickness of the first semiconductor device 200, thereby improving the thermal performance of the semiconductor package 100. Further, the plurality of first heat transfer vias HV1 may increase a rate of the heat transfer between the first semiconductor device 200 and the heat dissipation block 600, thereby improving the thermal performance of the semiconductor package 100.

Hereinafter, a method of manufacturing the semiconductor package 100 in FIG. 1 will be described.

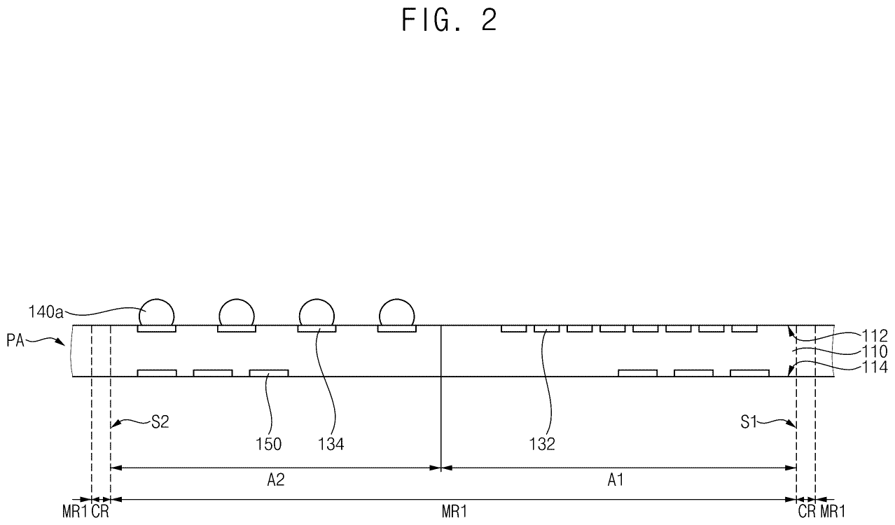

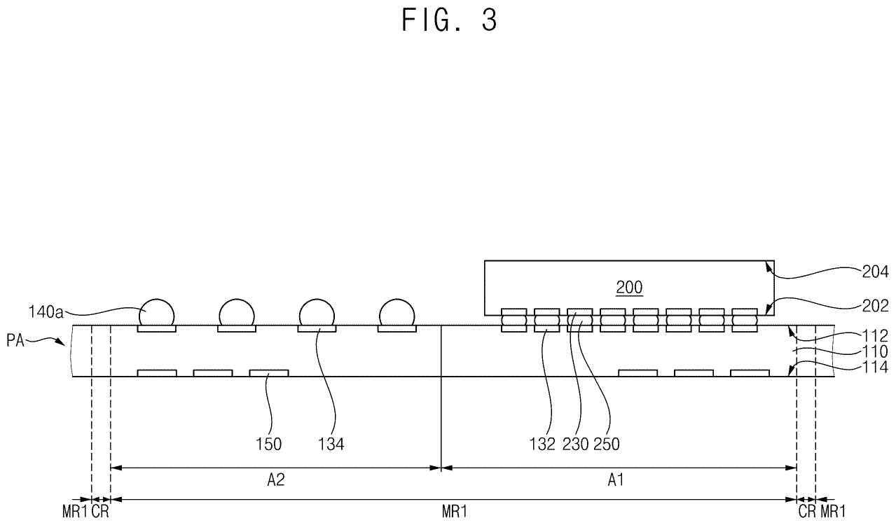

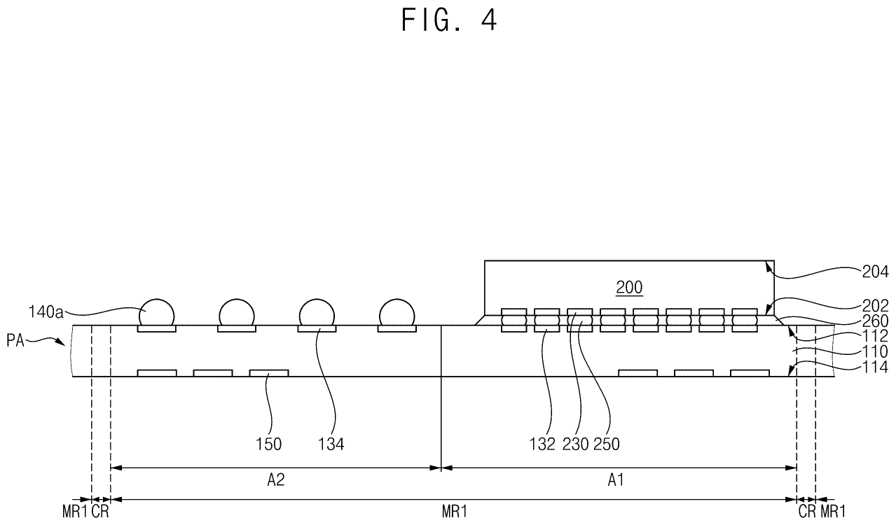

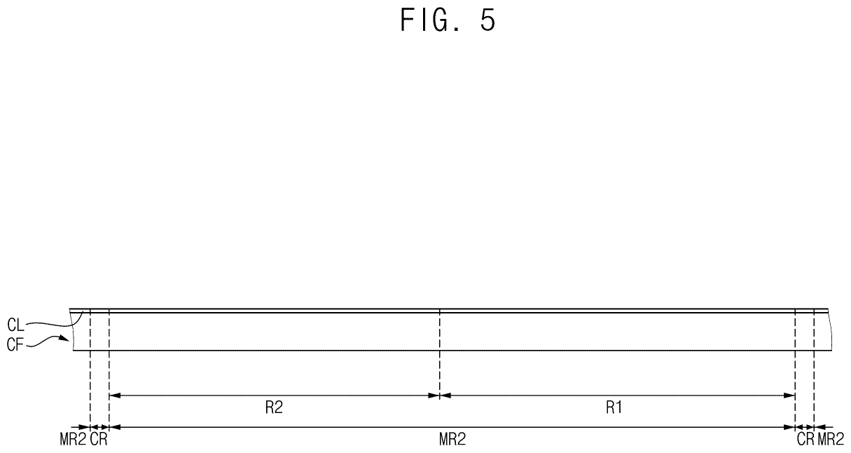

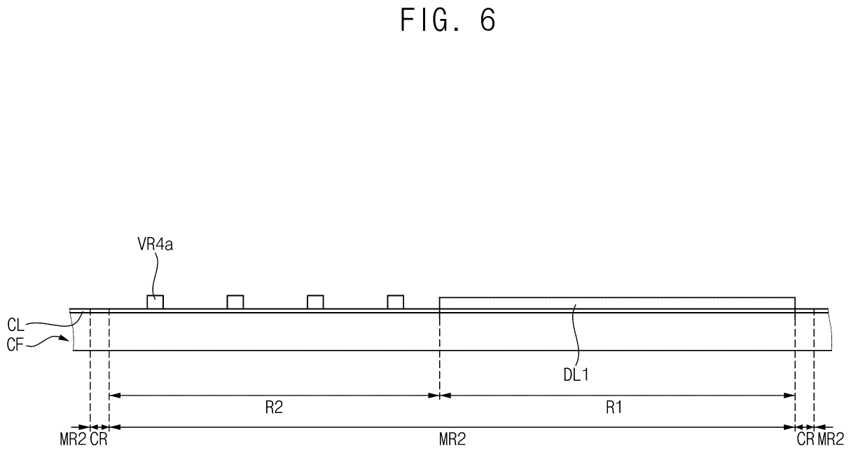

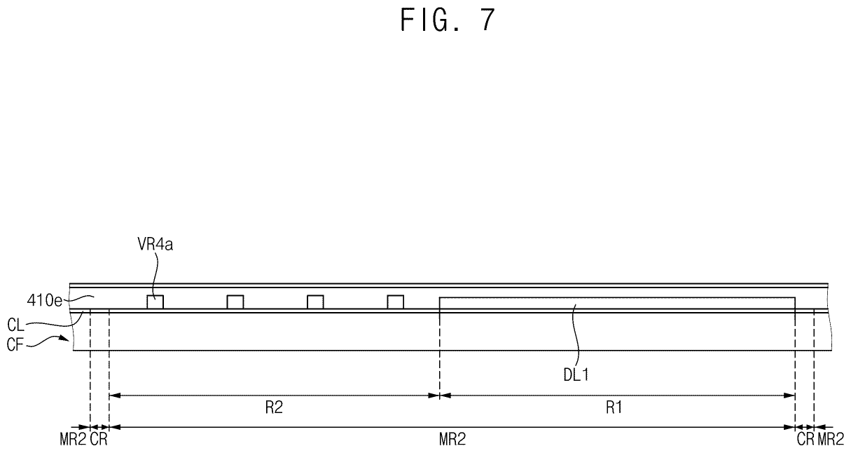

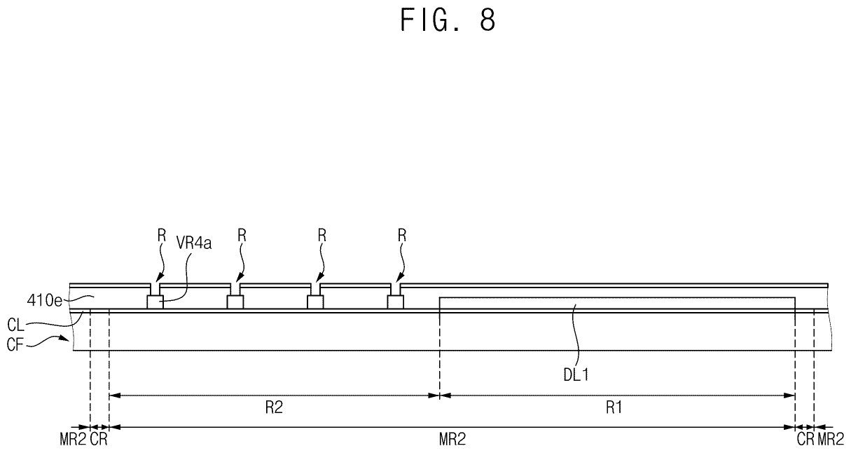

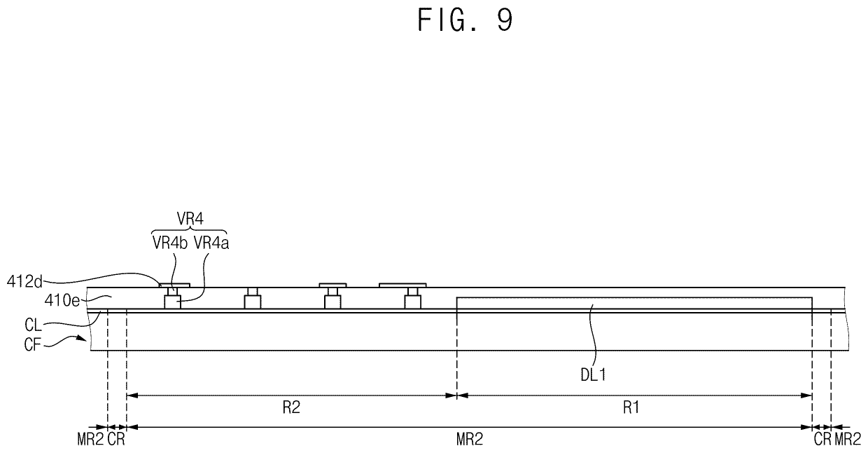

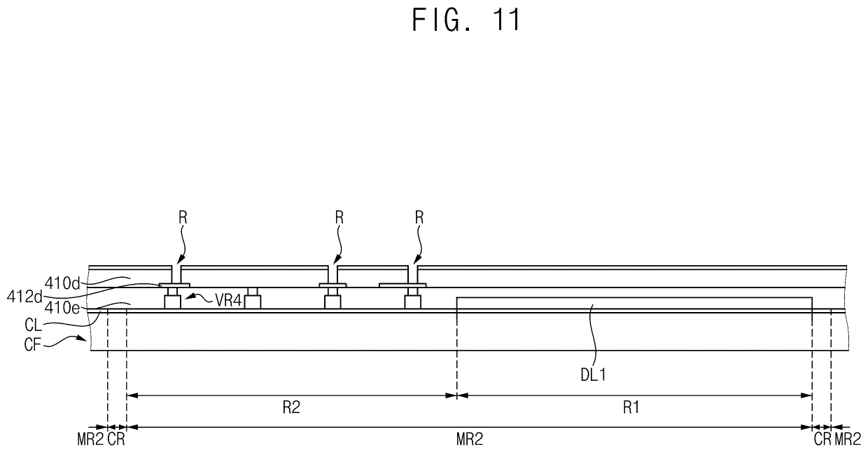

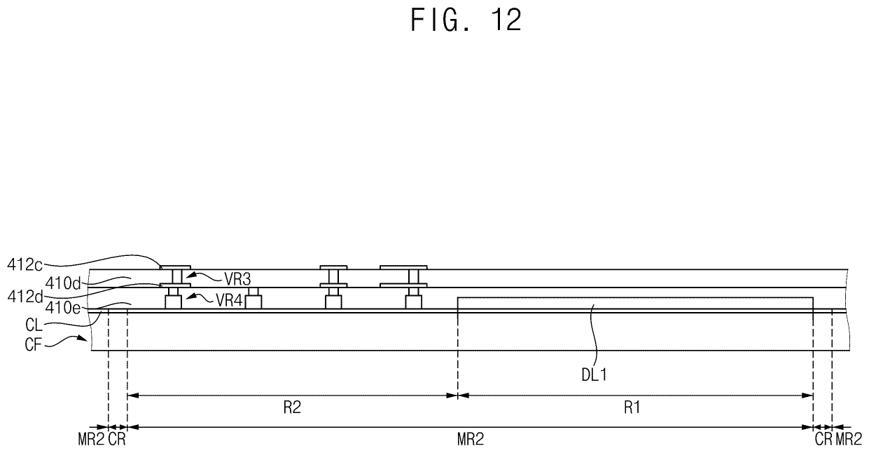

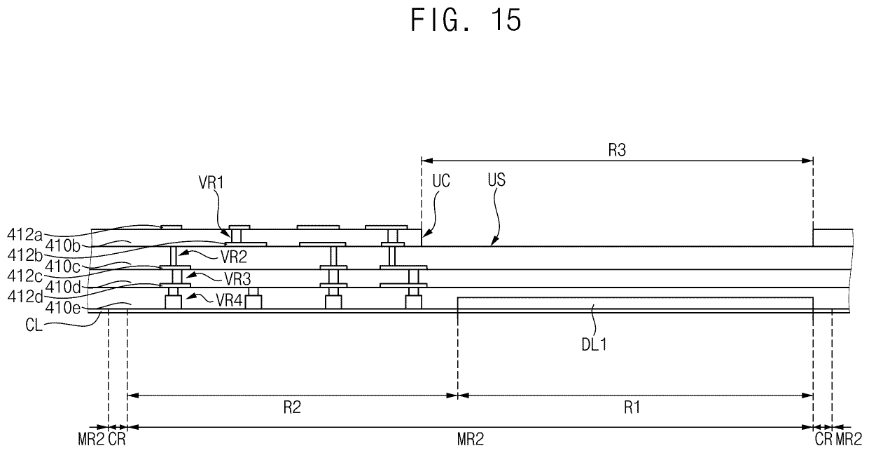

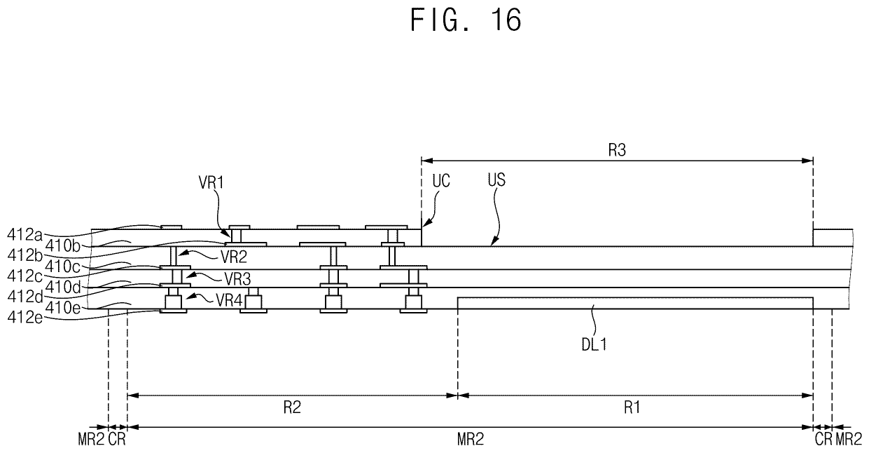

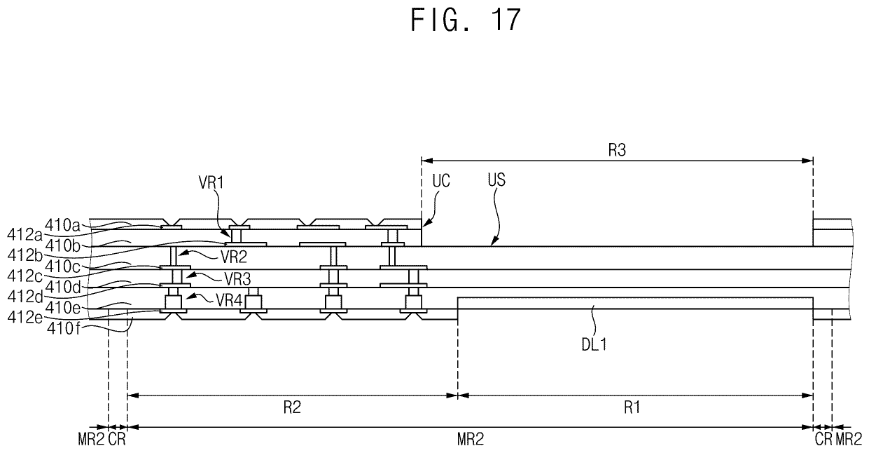

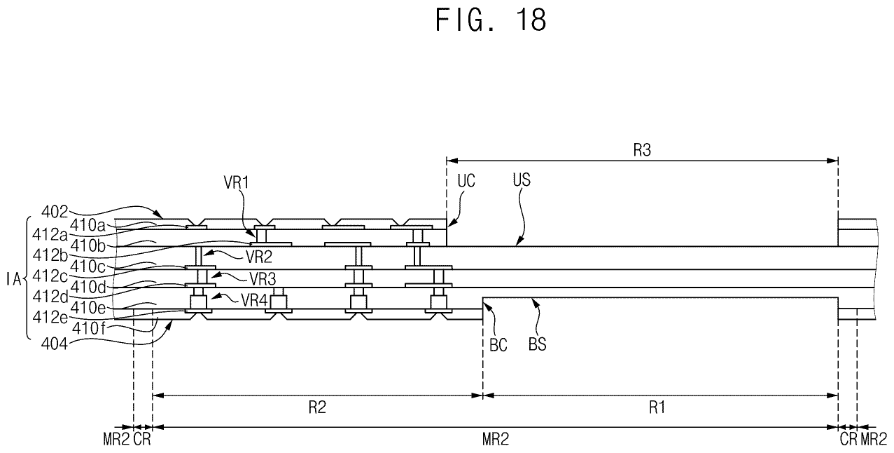

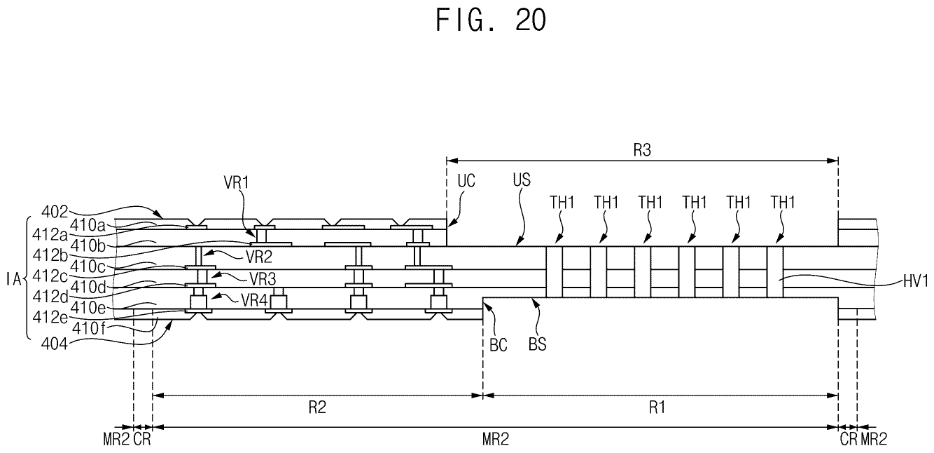

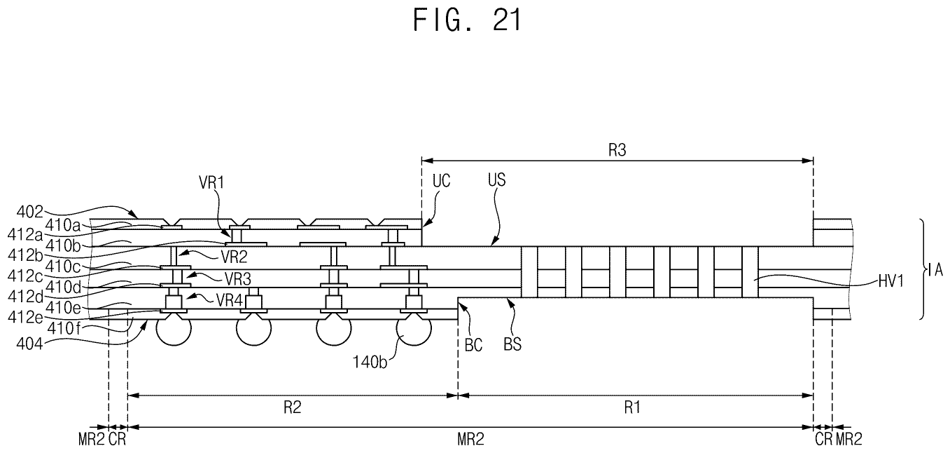

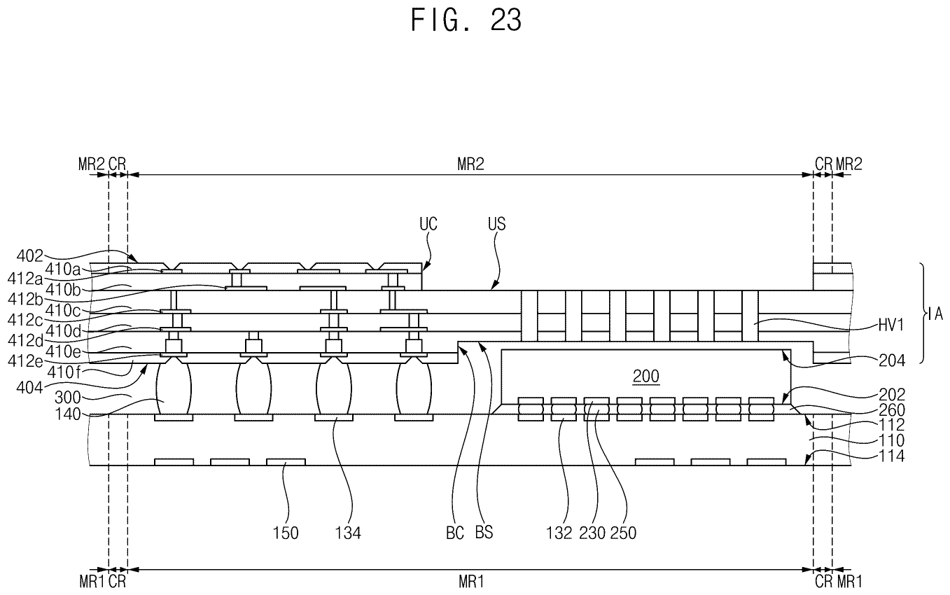

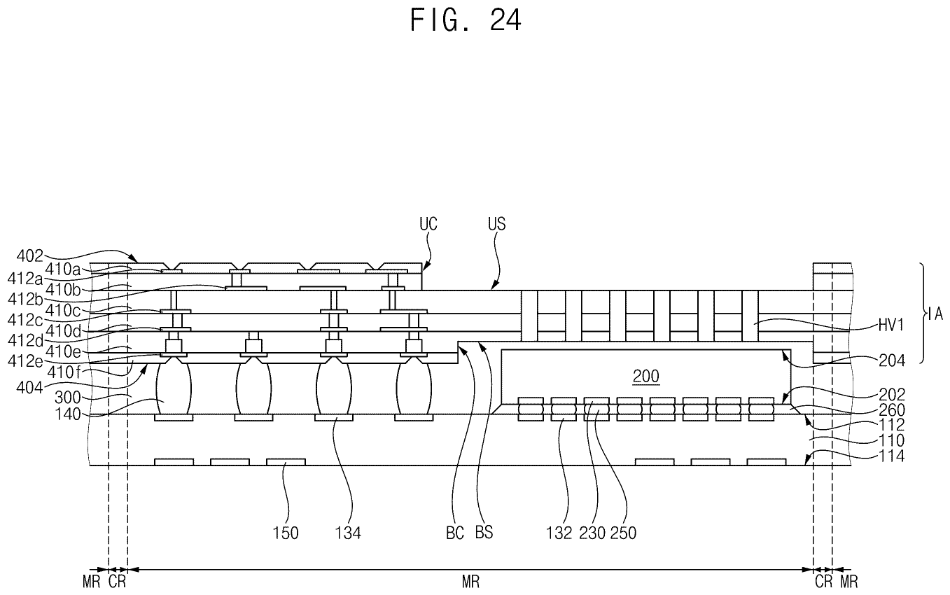

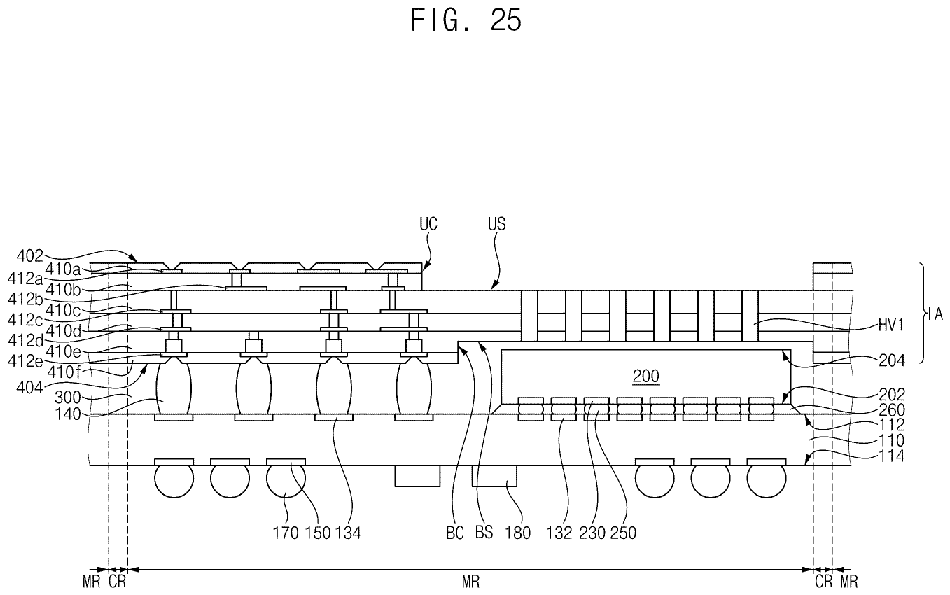

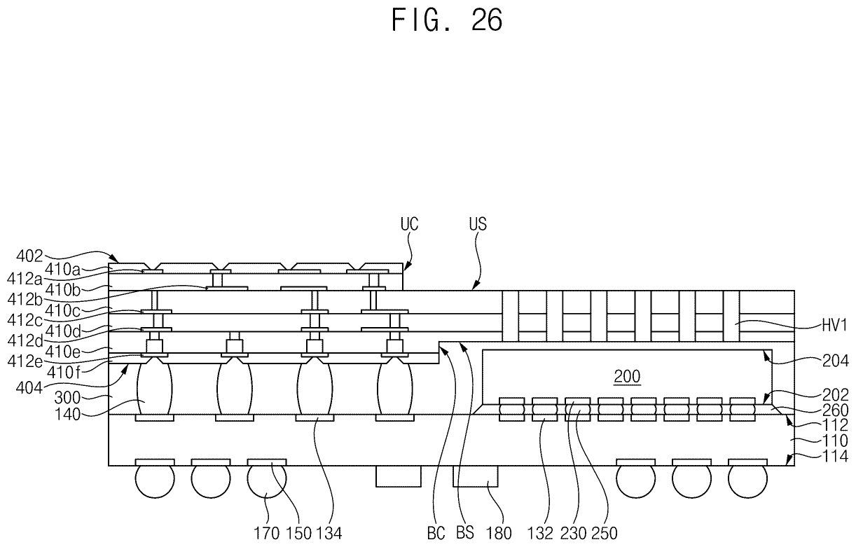

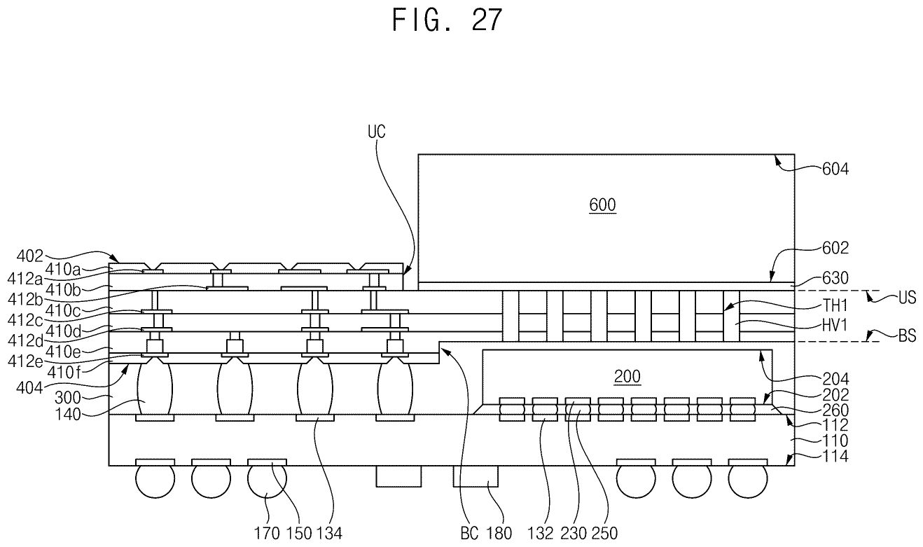

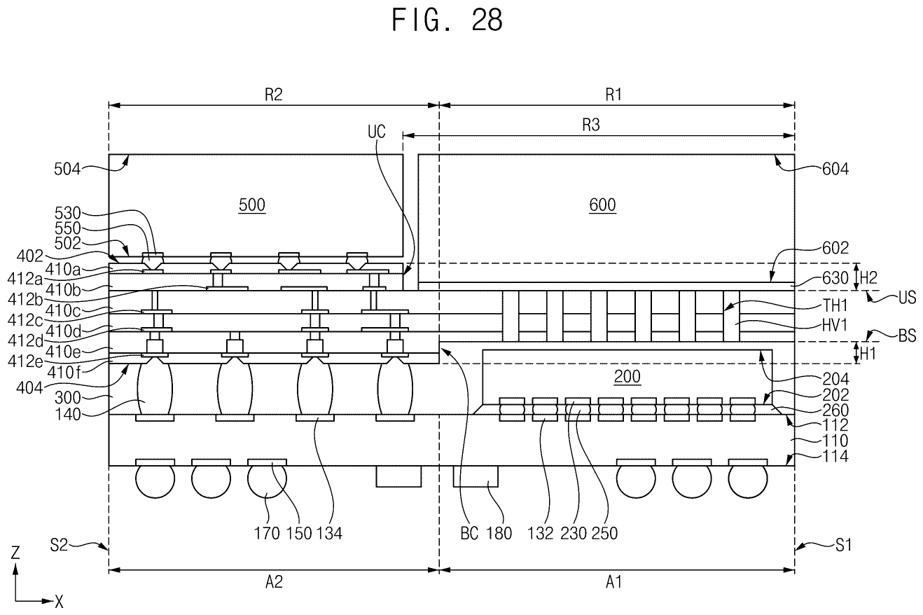

FIGS. 2 to 4 are views illustrating mounting a first semiconductor device on a substrate array in accordance with some embodiments. FIGS. 5 to 20 are views illustrating forming an interposer array in accordance with some embodiments. FIGS. 21 to 23 are views illustrating connecting the substrate array in FIG. 4 and the interposer array in FIG. 20. FIG. 24 is a cross-sectional view illustrating injecting a molding member between the substrate array and the interposer array in FIG. 23. FIG. 25 is a cross-sectional view illustrating attaching external connection members and passive elements to the substrate array in FIG. 24. FIG. 26 is a cross-sectional view illustrating forming a lower package by cutting the substrate array and interposer array in FIG. 25. FIG. 27 is a cross-sectional view illustrating attaching a heat dissipation block to the lower package in FIG. 26. FIG. 28 is a cross-sectional view illustrating mounting a second semiconductor device on the lower package in FIG. 27.

The semiconductor package manufactured by manufacturing processes illustrated in FIGS. 2 to 28 is substantially the same as the semiconductor package 100 described in FIG. 1, so identical components are denoted by the same reference numerals, and repeated descriptions of identical components are omitted.

Referring to FIGS. 2 to 4, a substrate array PA having a plurality of lower connection members 140a may be provided, a first semiconductor device 200 may be mounted on the substrate array PA, and an underfill member 260 may be injected underneath the first semiconductor device 200.

The substrate array PA may be provided, the substrate array PA including a plurality of first mounting regions MR1 and at least one cutting region CR connecting the plurality of first mounting regions MR1. The cutting region CR may be a region that is removed by a cutting process to be described later. Each of the plurality of first mounting regions MR1 may include a first substrate region A1 and a second substrate region A2. The plurality of lower connection members 140a may be respectively provided on the plurality of second upper substrate pads 134 provided in the second substrate region A2. In some embodiments, each of the plurality of lower connection members 140a may be on a different one of the plurality of second upper substrate pads 134.

The first semiconductor device 200 may be mounted on the first substrate region A1 of each of the plurality of first mounting regions MR1. For example, the first semiconductor device 200 may be mounted with a plurality of first conductive connection members 250 on the plurality of first upper substrate pads 132 provided in the first substrate region A1.

An underfill material may be injected between the front surface 202 of the first semiconductor device 200 and the upper surface 112 of the substrate array PA to form an underfill member 260 that covers the first conductive connection members 250 underneath the first semiconductor device 200.

Referring to FIGS. 5 to 20, an interposer array IA having an upper cavity UC and a lower cavity BC may be formed by stacking a plurality of insulation layers 410 and forming a plurality of internal wirings 412 in the plurality of insulation layers 410.

Referring again to FIGS. 5 to 9, a carrier CF having a base metal layer CL on an upper portion may be provided, a fifth insulation layer 410e may be attached to the base metal layer CL, and a plurality of fourth internal connection vias VR4 penetrating the fifth insulation layer 410e and a fourth wire 412d provided on the plurality of fourth internal connection vias VR4 may be formed.

Specifically, the carrier CF, which has a base metal layer CL on an upper portion, may be provided. The base metal layer CL may include a first interposer region R1 provided on a side portion and a second interposer region R2 adjacent to the first interposer region R1. For example, the carrier may be a base configured to form an interposer 400, so the carrier CF may be removed during a manufacturing process of an interposer 400.

Then, a plating process and an etching process may be performed on the base metal layer CL to form the plurality of first via structures VR4a provided in the second interposer region R2 and a first dummy layer DL1 provided in the first interposer region R1. For example, the plurality of first via structures VR4a and the first dummy layer DL1 may include a conductive metallic material. The first dummy layer DL1 may be provided in a region for forming a cavity during manufacturing process of the interposer 400 to be described later.

Further, a fifth insulation layer 410e covering the plurality of first via structures VR4a and the first dummy layer DL1 may be attached on the base metal layer CL. For example, the fifth insulation layer 410e may include an insulation layer and a metal coating layer covering a surface of the insulation layer. The fifth insulation layer 410e may include a material such as prepreg (PPG), copper clad laminate (CCL), resin coated copper (RCC), or the like.

Then, a drill process may be performed on the fifth insulation layer 410e to form a plurality of recesses R that expose the plurality of first via structures VR4a. For example, the drill process may include a laser drill process utilizing a laser or a mechanical drill process.

Subsequently, a plating process and an etching process may be performed on the fifth insulation layer 410e to form a plurality of second via structures VR4b filling the plurality of recesses R and to form the fourth wire 412d.

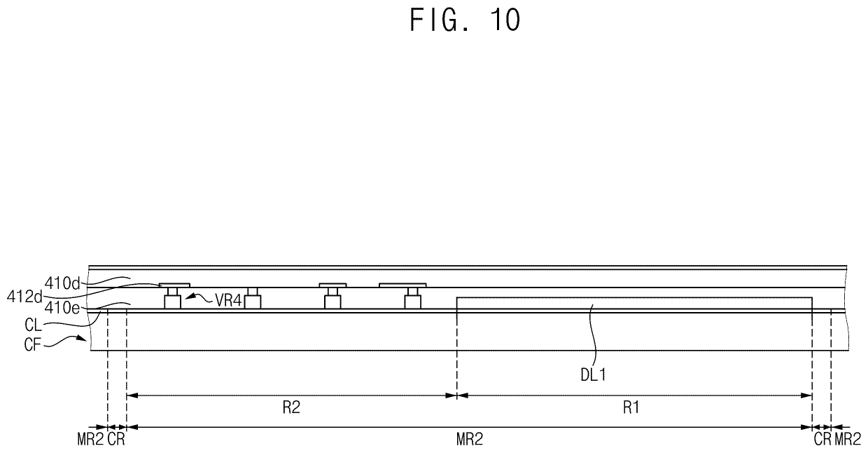

Referring again to FIGS. 10 to 12, the fourth insulation layer 410d may be attached to the fifth insulation layer 410e, and the plurality of third internal connection vias VR3 penetrating the fourth insulation layer 410d and the third wire 412c provided on the plurality of third internal connection vias VR3 may be formed.

Specifically, a fourth insulation layer 410d may be attached on the fifth insulation layer 410e to cover the fourth wire 412d. For example, the fourth insulation layer 410d may include an insulation layer and a metallic coating layer covering one surface of the insulation layer. The fourth insulation layer 410d may include a material such as prepreg (PPG), copper clad laminate (CCL), resin coated copper (RCC), or the like.

Then, a drill process may be performed on the fourth insulation layer 410d to form a plurality of recesses R exposing the fourth wire 412d. For example, the drill process may include a laser drill process utilizing a laser drill process or a mechanical drill process.

Subsequently, a plating process and an etching process may be performed on the fourth insulation layer 410d to form a plurality of third internal connection vias VR3 filling the plurality of recesses R and to form a third wire 412c.

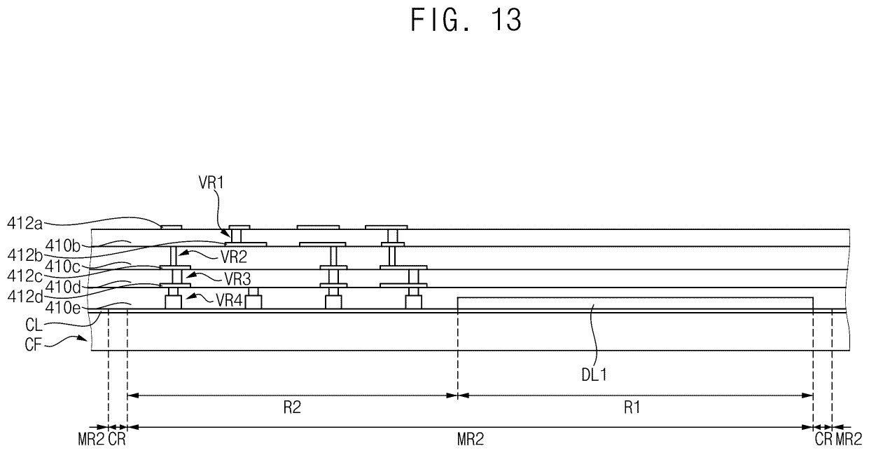

Referring again to FIG. 13, a third insulation layer 410c, the plurality of second internal connection vias VR2 and a second wire 412b may be formed by the same method as described with reference to FIGS. 10 to 12, and a fourth insulation layer 410b, a plurality of first internal connection vias VR1 and a first wires 412a may be formed by the same method as described with reference to FIGS. 10 to 12.

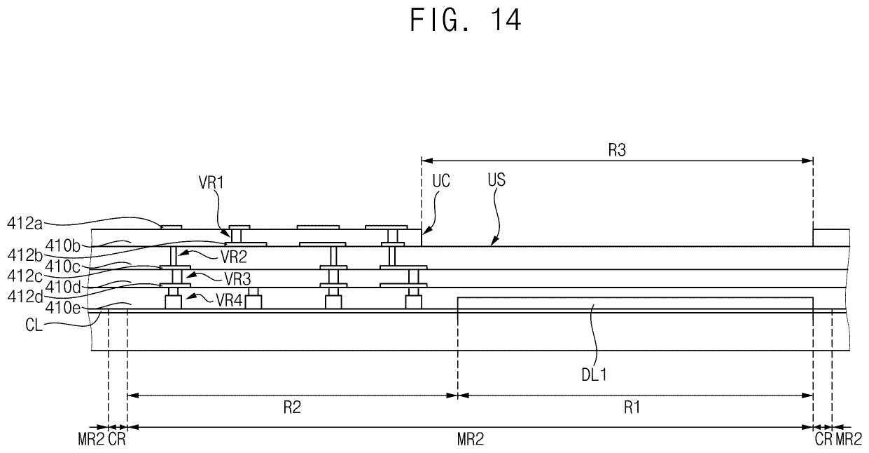

Referring again to FIGS. 14 to 18, an etch process and a drill process may be respectively performed on the second insulation layer 410b and the fifth insulation layer 410e to form an upper cavity UC and a lower cavity BC to expose an interior.

Specifically, the second insulation layer 410b may include a third interposer region R3 spaced apart from the first wire 412a in the first direction (X direction). An etching process and a drilling process may be performed on the third interposer region R3 of the second insulation layer 410b to form an upper cavity UC exposing the upper exposed surface US. For example, insulation material of the second insulation layer 410b may be removed by performing the drilling process, and a metallic material of the second insulation layer 410b may be removed by performing the etching process. While the figures illustrate the removal of the second insulation layer 410b, it will be understood that the present inventive concept is not limited thereto. Accordingly, depending on the depth of the cavity to be formed, the number and depth of insulation layers removed may be varied.

Then, the carrier CF may be removed, and an etching process may be performed on the base metal layer CL to form a fifth wire 412e on the fifth insulation layer 410e.

Then, a first insulation layer 410a may be formed on the second insulation layer 410b excluding the upper cavity UC, and a sixth insulation layer 410f may be formed on the fifth insulation layer 410e excluding the first dummy layer DL1. For example, the second insulation layer 410b and the sixth insulation layer 410f may be solder resist layers including a solder resist material.

Subsequently, an etching process may be performed on the first interposer region R1 to remove the first dummy layer DL1 to form the lower cavity BC including a lower exposed surface BS.

The lower cavity BC is illustrated as being formed by removing the first dummy layer DL1, but it will be appreciated that the present inventive concept is not limited to thereto. Thus, the lower cavity BC may be formed by performing an etching process and a drilling process on the insulation layer, the same as the upper cavity UC.

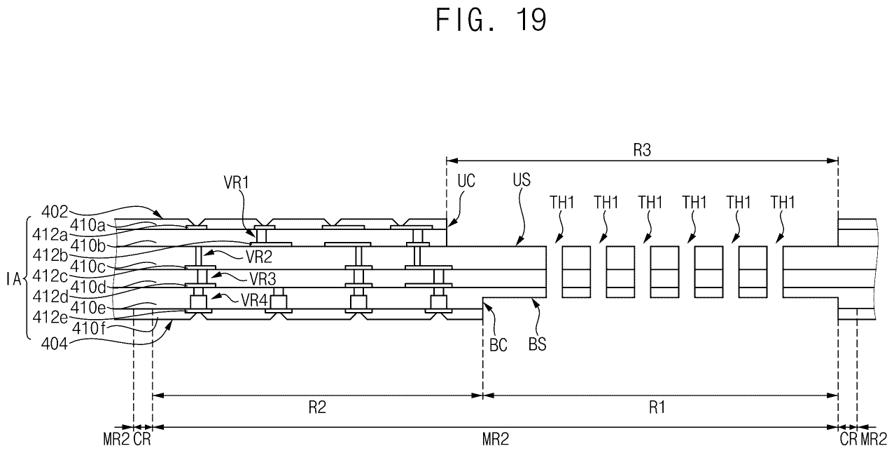

Referring again to FIGS. 19-21, the etching process and drilling process may be performed to form a plurality of first through holes TH1 connecting the upper cavity UC and the lower cavity BC, and the plating process may be performed to form a plurality of first heat transfer vias HV1 filling the plurality of first through holes TH1 to complete an interposer array IA including a plurality of interposers. For example, the interposer array IA may include a plurality of second mounting regions MR2 and a cutting region CR connecting the plurality of second mounting regions MR2. The cutting region CR may be a region that is removed by a cutting process to be described later.

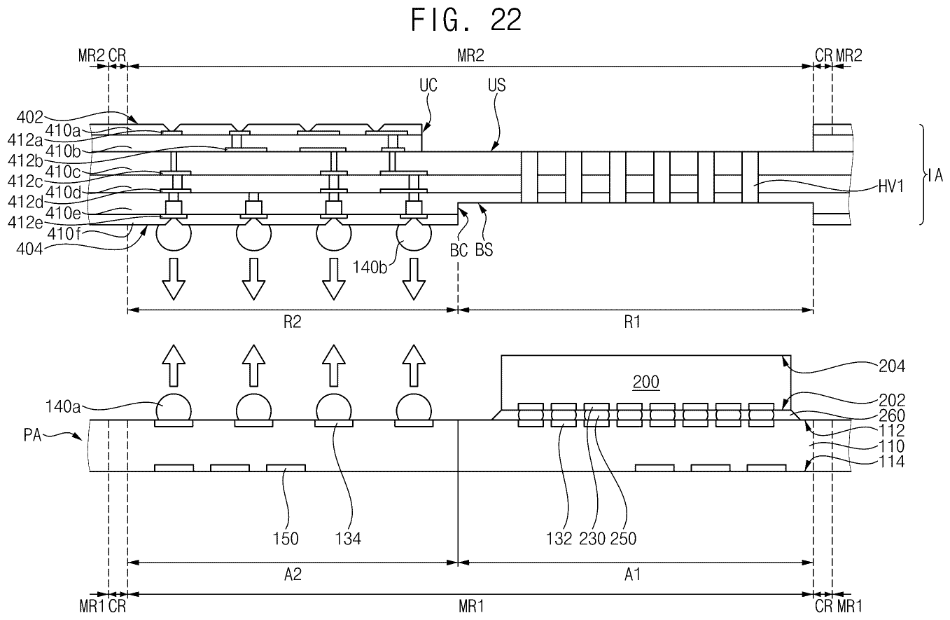

A plurality of upper connection members 140b may be attached to a lower portion of the interposer array IA. As shown in FIG. 22, the plurality of upper connection members 140b may be structures configured to connect the interposer array IA to the substrate array PA.

Referring to FIGS. 22 and 23, the plurality of lower connection members 140a may be respectively in contact with the plurality of upper connection members 140b by moving the interposer array IA toward the substrate array PA such that a portion of the first semiconductor device 200 is within the lower cavity BC. The plurality of lower connection members 140a and the plurality of upper connection members 140b may be combined to form a plurality of vertical conductive connectors 140.

Specifically, the upper surface 402 of the interposer array IA may be adsorbed and positioned above the substrate array PA using a transportation apparatus. The plurality of second mounting regions MR2 and the plurality of first mounting regions MR1 may be aligned such that each of the plurality of lower connection members 140a correspond each of the plurality of upper connection members 140b. Then, the interposer array IA may be moved toward the substrate array PA such that the plurality of lower connection members 140a and the plurality of upper connection members 140b are in contact with each other. At this time, a portion of the first semiconductor device 200 may be within the lower cavity BC. Thereafter, a thermal compression bonding process may be performed to form the plurality of vertical conductive connectors 140 by applying high temperature and pressure.

Referring to FIG. 24, a molding material may be injected between the interposer array IA and the substrate array PA to form a molding member 300 that covers the plurality of vertical conductive connectors 140 and the first semiconductor device 200. For example, the molding member 300 may fill a space between the lower surface 404 of the interposer array IA and the substrate array PA and the lower cavity BC of the interposer array IA.

Referring to FIG. 25, a plurality of external connection members 170 and a plurality of passive components 180 may be attached to a lower portion of the substrate array PA. For example, the plurality of external connection members 170 may be attached to the plurality of lower substrate pads 150 that is exposed from the lower surface 114 of the substrate array PA.

Referring to FIG. 26, a cutting process may be performed along the cut regions CR of the substrate array PA and interposer array IA to individualize the lower package. The lower package may include a package substrate 110, a first semiconductor device 200, a molding member 300, and an interposer 400.

Referring to FIG. 27, the heat dissipation block 600 may be attached to the interposer 400 such that at least a portion of the heat dissipation block 600 is within the upper cavity UC. The heat dissipation block 600 may be within the upper cavity UC of the interposer 400 in an individualized lower package. For example, the heat dissipation block 600 may be attached to the upper exposed surface US of the upper cavity UC with the first thermal adhesive member 630 which is provided on a lower portion of the heat dissipation block 600.

In this case, heat generated by the first semiconductor device 200 may be easily dissipated to outside with the plurality of first heat transfer vias HV1 and the heat dissipation block 600 which are located above the first semiconductor device 200. In particular, due to the upper cavity UC and lower cavity BC of the interposer 400, a distance between the first semiconductor device 200 and the heat dissipation block 600 may be close, thereby heat generated by the first semiconductor device 200 being easily transferred to the heat dissipation block 600. In other words, the first semiconductor device 200 and the heat dissipation block 600 may have a small distance between them. Thus, the thermal performance of the semiconductor package may be improved.

Referring to FIG. 28, the semiconductor package 100 of FIG. 1 may be completed by mounting a second semiconductor device 500 on the interposer 400 of the individualized lower package. For example, the second semiconductor device 500 may be mounted on the interposer 400 with a plurality of second conductive connection members 550 provided on the first wire 412a which is exposed by the first insulation layer 410a.

Hereinafter, the semiconductor package 101 in accordance with some embodiments will be described.

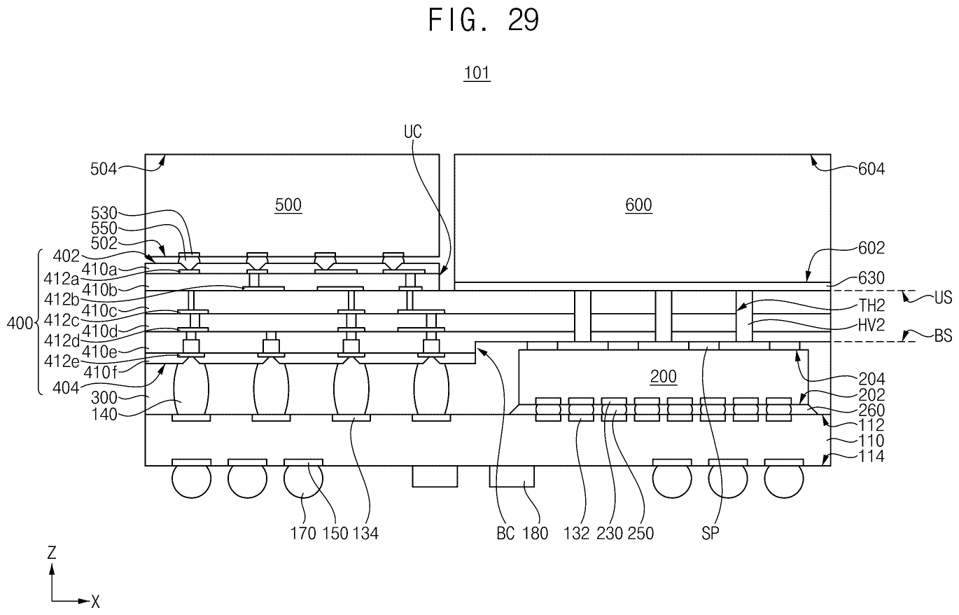

FIG. 29 is a cross-sectional view illustrating a semiconductor package in accordance with some embodiments.

Referring to FIG. 29, the semiconductor package 101 includes a package substrate 110, a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 in a first direction (X direction).

The semiconductor package 101 illustrated in FIG. 29 is substantially identical to the semiconductor package 100 described in FIG. 1 excluding the support portion SP, so identical components are denoted by the same reference numerals and repeated descriptions of identical components are omitted.

The interposer 400 may include a plurality of second through holes TH2 connecting the lower cavity BC and the upper cavity UC, and a plurality of second heat transfer vias HV2 within the plurality of second through holes TH2. For example, the plurality of second heat transfer vias HV2 may extend from a lower exposed surface BS exposed by the lower cavity BC to an upper exposed surface US exposed by the top cavity UC.

The interposer 400 may further include a plurality of support portions SP provided on the lower exposed surface BS.

Each of the plurality of support portions SP may be provided between the lower exposed surface BS of the interposer 400 and the backside surface 204 of the first semiconductor device 200 to be in contact with the backside surface 204 of the first semiconductor device 200. The plurality of support portions SP may be structures configured to stably support the interposer 400 between the interposer 400 and the first semiconductor device 200. For example, the plurality of support portions SP may include the same material as the sixth insulation layer 410f. The plurality of support portions SP may include a solder resist material.

Hereinafter, a method of manufacturing the semiconductor package 101 in FIG. 29 will be described.

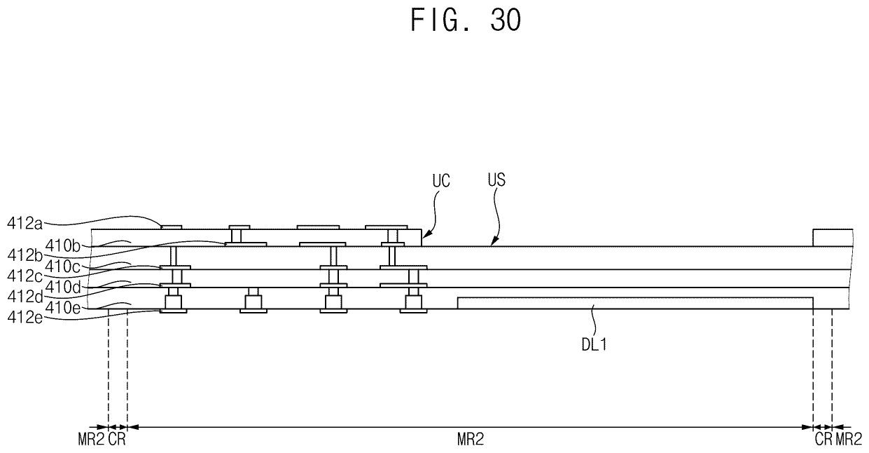

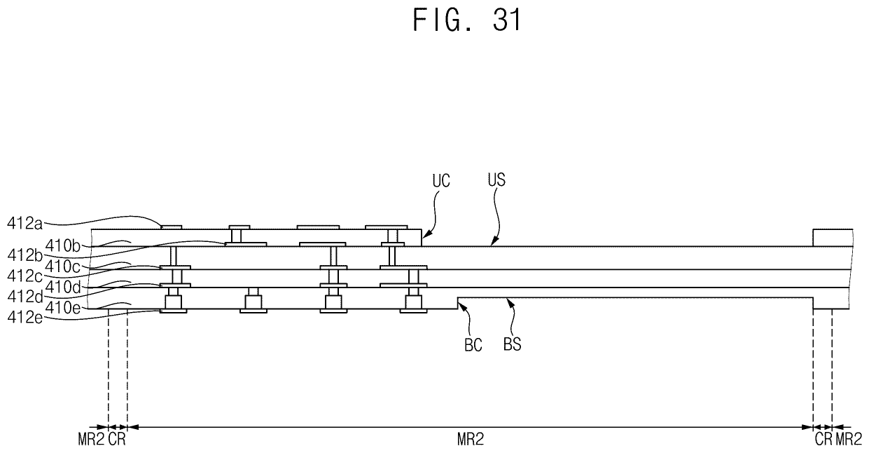

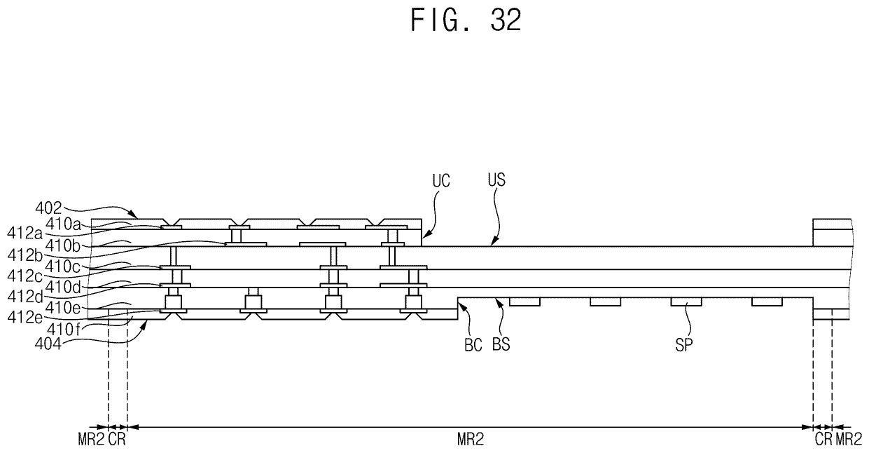

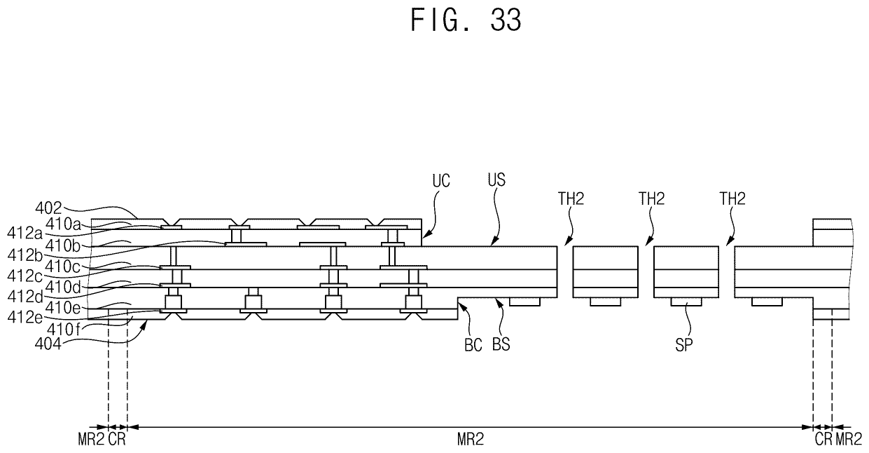

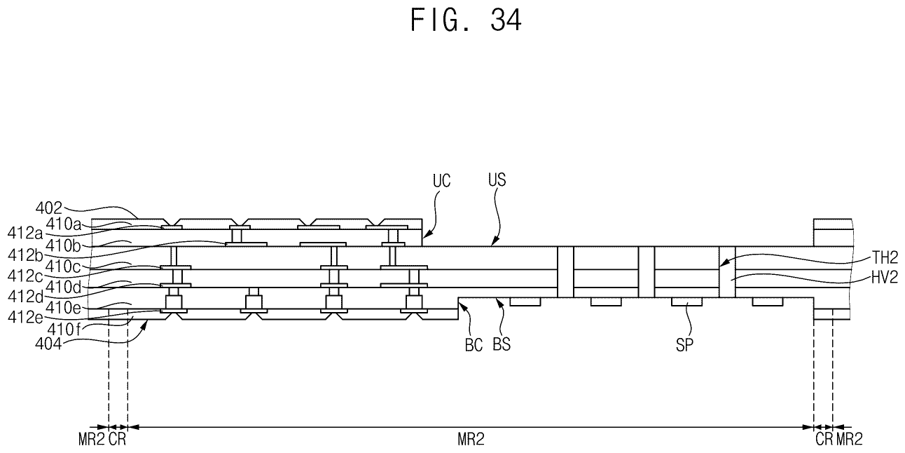

FIGS. 30 and 31 are views illustrating removing a first dummy layer to form a lower cavity. FIG. 32 is a view illustrating forming a plurality of support portions within the lower cavity. FIGS. 33 and 34 are views illustrating forming a plurality of second heat transfer vias connecting the lower cavity and the upper cavity.

The semiconductor package manufactured by the manufacturing process illustrated in FIGS. 30 to 34 is substantially the same as the semiconductor package 101 described in FIG. 29, so identical components are denoted by the same reference numerals, and repeated descriptions of identical components are omitted.

Referring to FIGS. 30 and 31, the first dummy layer DL1 may be removed to form a lower cavity BC having a lower exposed surface BS by performing an etching process on the fifth insulation layer 410e.

Referring to FIG. 32, a first insulation layer 410a may be formed on an upper portion of the second insulation layer 410b excluding the upper cavity UC, and a sixth insulation layer 410f may be formed on an upper portion of the fifth insulation layer 410e excluding the lower cavity BC. Further, a plurality of support portions SP may be formed within the lower cavity BC. For example, the second insulation layer 410b, the sixth insulation layer 410f, and the plurality of support portions SP may be solder resist layers including a solder resist material.

Referring to FIGS. 33 and 34, an etching process and a drilling process may be performed on regions, which are not overlapped with the plurality of support portions SP, among the upper exposed surface US to form a plurality of second through holes TH2 connecting the upper cavity UC and the lower cavity BC, and a plating process may be performed to form a plurality of second heat transfer vias HV2 filling the plurality of second through holes TH2, thus an interposer array IA including a plurality of interposers may be completed.

Hereinafter, a semiconductor package 102 will be described in accordance with some embodiments.

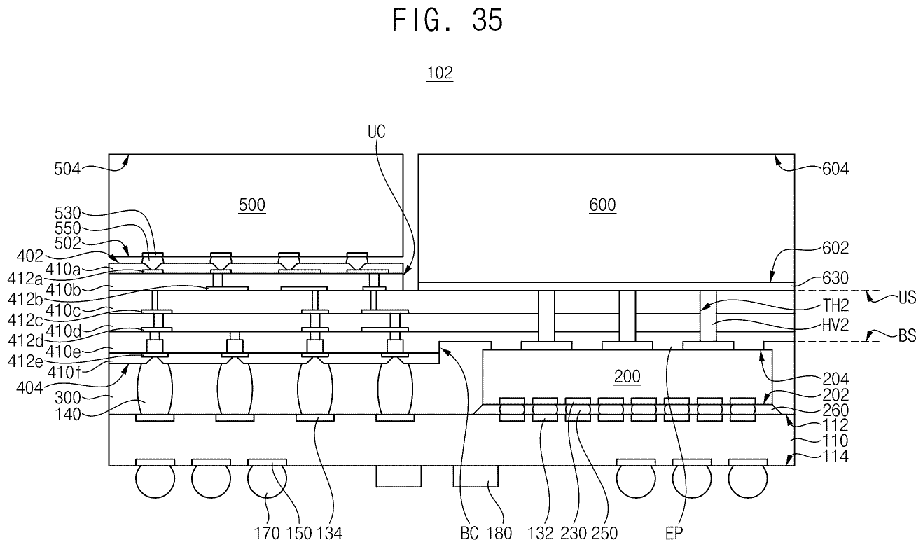

FIG. 35 is a cross-sectional view illustrating a semiconductor package in accordance with some embodiments.

Referring to FIG. 35, a semiconductor package 102 may include a package substrate 110, a first semiconductor device 200 mounted on the package substrate 110, a molding member 300 provided on the package substrate 110, an interposer 400 provided on the molding member 300 to cover the first semiconductor device 200, a second semiconductor device 500 mounted on the interposer 400, and a heat dissipation block 600 stacked on the interposer 400 to be spaced apart from the second semiconductor device 500 in a first direction (X direction).

The semiconductor package 102 illustrated in FIG. 35 is substantially the same as the semiconductor package 100 described in FIG. 1, except for the extension portions EP, so identical components are denoted by the same reference numerals and repeated descriptions of identical components are omitted.

The interposer 400 may include a plurality of second through holes TH2 connecting the lower cavity BC and the upper cavity UC, and a plurality of second heat transfer vias HV2 provided within the plurality of second through holes TH2. For example, the plurality of second heat transfer vias HV2 may extend from the lower exposed surface BS of the lower cavity BC to the upper exposed surface US of the upper cavity UC.

The interposer 400 may further include a plurality of extension portions EP respectively extending from the lower exposed surface BS to the backside surface 204 of the first semiconductor device 200. The plurality of extension portions EP may be structures configured to stably support the interposer 400 between the interposer 400 and the first semiconductor device 200. For example, the plurality of extension portions EP may include the same material as the fifth insulation layer 410e.

Hereinafter, a method of manufacturing the semiconductor package 102 in FIG. 35 will be described.

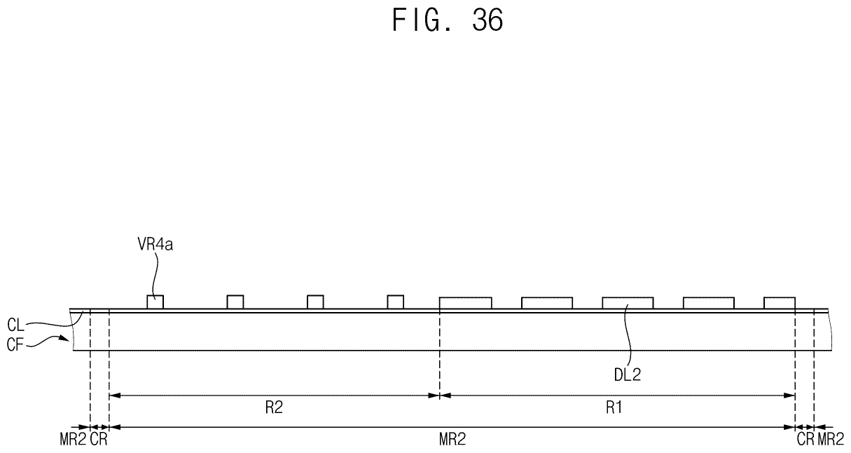

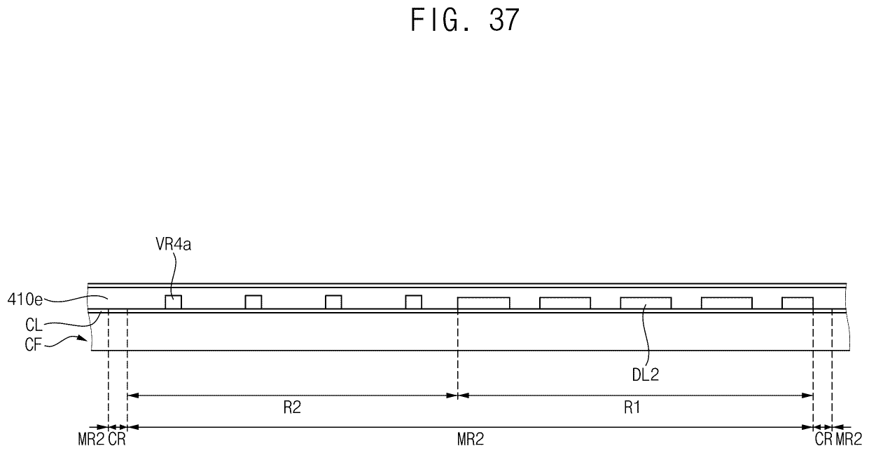

FIG. 36 is a cross-sectional view illustrating forming a plurality of second dummy layers on a base metal layer. FIG. 37 is a cross-sectional view illustrating attaching a fifth insulation layer covering the plurality of second dummy layers to the base metal layer.

The semiconductor package manufactured by the manufacturing process illustrated in FIGS. 36 and 37 is substantially the same as the semiconductor package 102 described in FIG. 35, so identical components are denoted by the same reference numerals, and repeated descriptions of identical components are omitted.

Referring to FIG. 36, a plating process and an etching process may be performed to form a plurality of first via structures VR4a provided within the second interposer region R2 and a plurality of second dummy layers DL2 provided within the first interposer region R1.

The plurality of second dummy layers DL2 may be provided along a first direction (X direction) on the first interposer region R1, which is a cavity forming region. The cavity forming region may be a region for forming a cavity during processes for manufacturing the interposer 400. The plurality of second dummy layers DL2 may be removed to form the lower cavity BC by an etching process to be described later. For example, the plurality of first via structures VR4a and the plurality of second dummy layers DL2 may include a conductive metallic material.

Referring to FIG. 37, a fifth insulation layer 410e covering the plurality of first via structures VR4a and the plurality of second dummy layers DL2 may be attached to a base metal layer CL. For example, the fifth insulation layer 410e may include an insulation layer and a metal coating layer covering a surface of the insulation layer. The fifth insulation layer 410e may include a material such as prepreg (PPG), copper clad laminate (CCL), resin coated copper (RCC), or the like.

The plurality of second dummy layers DL2 provided within the fifth insulation layer 410e may be removed to form the lower cavity BC and a plurality of extension portions EP provided within the lower cavity BC by an etching process to be described later.

Hereinafter, a semiconductor package 103 in accordance with some embodiments will be described.

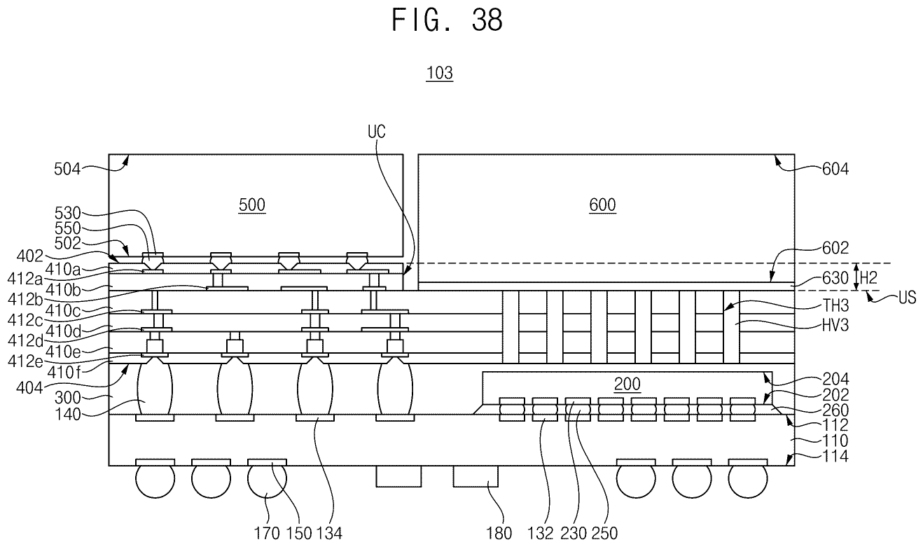

FIG. 38 is a cross-sectional view illustrating a semiconductor package in accordance with some embodiments.

Referring to FIG. 38, the semiconductor package 103 may include a package substrate 110, a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 in a first direction (X direction).

The semiconductor package 103 illustrated in FIG. 38 is substantially identical to the semiconductor package 100 described in FIG. 1 excluding the interposer 400, so identical components are denoted by the same reference numerals and repeated descriptions of identical components are omitted.

In some embodiments, the interposer 400 may include a plurality of insulation layers 410 and a plurality of internal wirings 412 within the plurality of insulation layers 410. The interposer 400 may include an upper surface 402 and a lower surface 404 that face each other. In other words, the upper surface 402 and the lower surface 404 may be directly opposite of one another. The interposer 400 may include a plurality of internal vias VR1, VR2, VR3, VR4 electrically connecting each of the plurality of internal wiring 412.

The interposer 400 may be on the package substrate 110 such that the plurality of vertical conductive connectors 140 is between the package substrate 110 and the interposer 400. For example, the interposer 400 may be on the package substrate 110 to be supported by the plurality of vertical conductive connectors 140 and the molding member 300.

The interposer 400 may include a first interposer region R1 located above the first semiconductor device 200 and a second interposer region R2 adjacent to the first interposer region R1. For example, the second R2 interposer region may be a region surrounding the first interposer region R1. A plurality of internal wirings 412 may be located within the second interposer region R2 to be electrically connected to a plurality of vertical conductive connectors 140. The interposer 400 may include a third interposer region R3 among the upper surface 402 at least partially overlapped with the first interposer region R1.

The interposer 400 may include an upper cavity UC provided on the third interposer region R3 to have a second depth H2 from the upper surface 402. The upper cavity UC may be a receiving recess for receiving a heat dissipation block 600 therein, to be described later. For example, the recess may be a recess having a square shape, when viewed in a plan view.

The interposer 400 may include a plurality of third heat transfer vias HV3 respectively provided between the upper cavity UC and the first semiconductor device 200. Each of the plurality of third heat transfer vias HV3 may extend from the upper cavity UC to the lower surface 404. For example, the plurality of third heat transfer vias HV3 may have a plurality of third through holes TH3 connecting the upper exposed surface US of the upper cavity UC and the lower surface 404 of the interposer 400, respectively. The plurality of third heat transfer vias HV3 may be provided within the plurality of third through holes TH3 to respectively extend between the upper cavity UC and the lower surface 404 of the interposer 400.

The interposer 400 may include a first portion with the upper cavity UC and a second portion with a plurality of internal wirings 412. For example, the first portion may be provided on the molding member 300 to be located above the first semiconductor device 200, and the second portion may be provided on the plurality of vertical conductive connectors 140. The plurality of third heat transfer vias HV3 may be provided within the first portion.

Hereinafter, a semiconductor package 104 in accordance with some embodiments will be described.

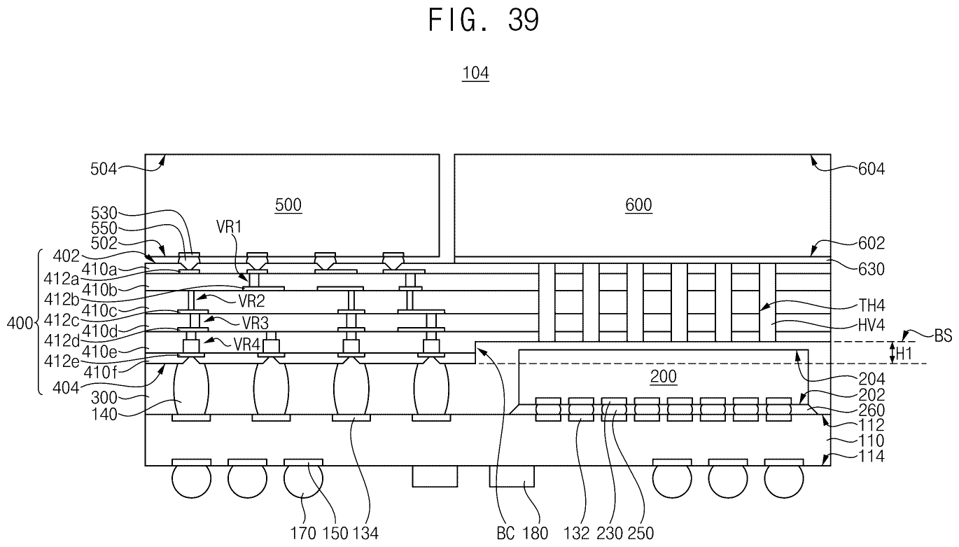

FIG. 39 is a cross-sectional view illustrating a semiconductor package in accordance with some embodiments.

Referring to FIG. 39, a semiconductor package 104 may include a package substrate 110, a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 in a first direction (X direction).

The semiconductor package 104 illustrated in FIG. 39 is substantially the same as the semiconductor package 100 described in FIG. 1, except for the interposer 400, so identical components are denoted by the same reference numerals and repeated descriptions of identical components are omitted.

In some embodiments, the interposer 400 may include a plurality of insulation layers 410 and a plurality of internal wirings 412 within the plurality of insulation layers 410. The interposer 400 may include an upper surface 402 and a lower surface 404 that face each other. In other words, the upper surface 402 and the lower surface 404 may be directly opposite of one another. The interposer 400 may include a plurality of internal vias VR1, VR2, VR3, VR4 that electrically connect each of the plurality of internal wiring 412.

The interposer 400 may be on the package substrate 110 such that the plurality of vertical conductive connectors 140 is between the package substrate 110 and the interposer 400. For example, the interposer 400 may be on the package substrate 110 to be supported by the plurality of vertical conductive connectors 140 and the molding member 300.

The interposer 400 may include a first interposer region R1 located above the first semiconductor device 200 and a second interposer region R2 adjacent to the first interposer region R1. For example, the second interposer region R2 may be a region surrounding the first interposer region R1. A plurality of internal wirings 412 may be located within the second interposer region R2 to be electrically coupled to a plurality of vertical conductive connectors 140. The interposer 400 may include a third interposer region R3 among the upper surface 402 at least partially overlapped with the first interposer region R1.

The interposer 400 may include a lower cavity BC provided on the first interposer region R1 to have a first depth H1 from the lower surface 404. The lower cavity BC may be a receiving recess for receiving the first semiconductor device 200 therein. For example, the receiving recess may be a receiving recess having a square shape, when viewed in a plan view.

The interposer 400 may include a plurality of fourth heat transfer vias HV4 respectively provided between the first semiconductor device 200 and the heat dissipation block 600. The plurality of fourth heat transfer vias HV4 may each extend from the upper surface 402 to the lower cavity BC. For example, the plurality of fourth heat transfer vias HV4 may have a plurality of fourth through holes TH4 connecting the upper surface 402 of the interposer 400 and the lower exposed surface BS of the lower cavity BC, respectively. A plurality of fourth heat transfer vias HV4 may be provided within the plurality of fourth through holes TH4 to extend between the lower cavity BC and the upper surface 402 of the interposer 400, respectively.

The interposer 400 may include a first portion with the lower cavity BC and a second portion with a plurality of internal wirings 412. For example, the first portion may be provided on the molding member 300 to be located above the first semiconductor device 200, and the second portion may be provided on the plurality of vertical conductive connectors 140. The plurality of fourth heat transfer vias HV4 may be provided within the first portion.

Hereinafter the following, a semiconductor package 105 in accordance with some embodiments will be described.

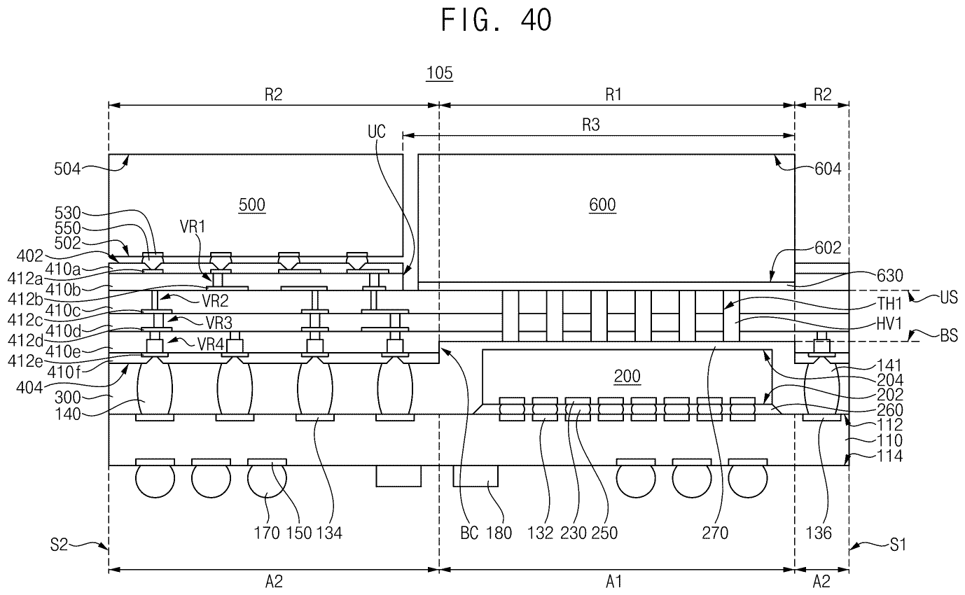

FIG. 40 is a cross-sectional view illustrating a semiconductor package in accordance with some embodiments.

Referring to FIG. 40, a semiconductor package 105 may include a package substrate 110, a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 in a first direction (X direction).

The semiconductor package 105 illustrated in FIG. 40 is substantially identical to the semiconductor package 100 described in FIG. 1 except for the plurality of support members 141, so identical components are denoted by the same reference numerals and repeated descriptions of identical components are omitted.

In some embodiments, the package substrate 110 may have a first side portion S1 and a second side portion S2 that face each other. In other words, the first side portion S1 and the second side portion S2 may be directly opposite of one another. An upper surface 112 of the package substrate 110 may include a first substrate region A1 adjacent to the first side portion S1 and a second substrate region A2 adjacent to the first substrate region A1. For example, the second substrate region A2 may be a region surrounding the first substrate region A1.

The plurality of upper substrate pads 130 may include a plurality of first upper substrate pads 132 provided within the first substrate region A1, and the plurality of upper substrate pads 130 may include a plurality of second upper substrate pads 134 and a plurality of third upper substrate pads 136 provided within the second substrate region A2. For example, the plurality of second upper substrate pads 134 may be in a region adjacent to the second side portion S2, and the plurality of third upper substrate pads 136 may be in a region adjacent to the first side portion S1.

The package substrate 110 may further include a plurality of vertical conductive connectors 140 on each of the plurality of second upper substrate pads 134 and a plurality of support members 141 on each of the plurality of third upper substrate pads 136. For example, the plurality of vertical conductive connectors 140 and the plurality of support members 141 may each include a conductive metallic material.

The plurality of vertical conductive connectors 140 may be structures configured to electrically connect the interposer 400 and the package substrate 110 and support the interposer 400. In contrast, the plurality of support members 141 may be structures configured to support the interposer 400 without electrical connection between the interposer 400 and the package substrate 110.

While the figures only illustrate the plurality of support members 141 and the plurality of internal wiring 412 not being connected, it will be understood that the present inventive concept is not limited thereto. Accordingly, the plurality of support members 141 may be electrically connected to the plurality of internal wiring 412 such that electrical signals may be transmitted through the plurality of support members 141.

Hereinafter, a method of manufacturing the semiconductor package 105 in FIG. 40 will be described.

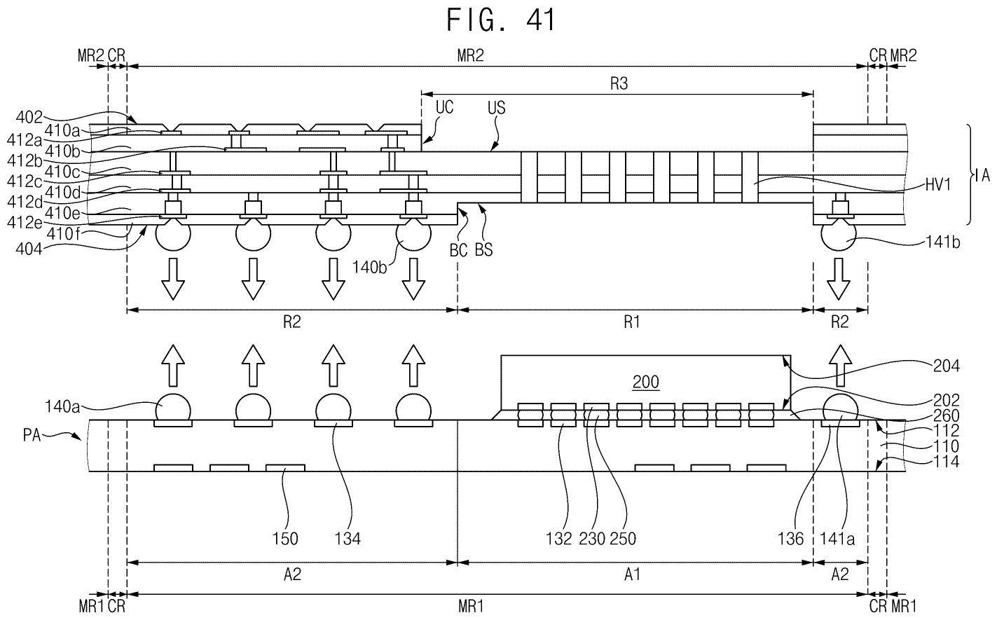

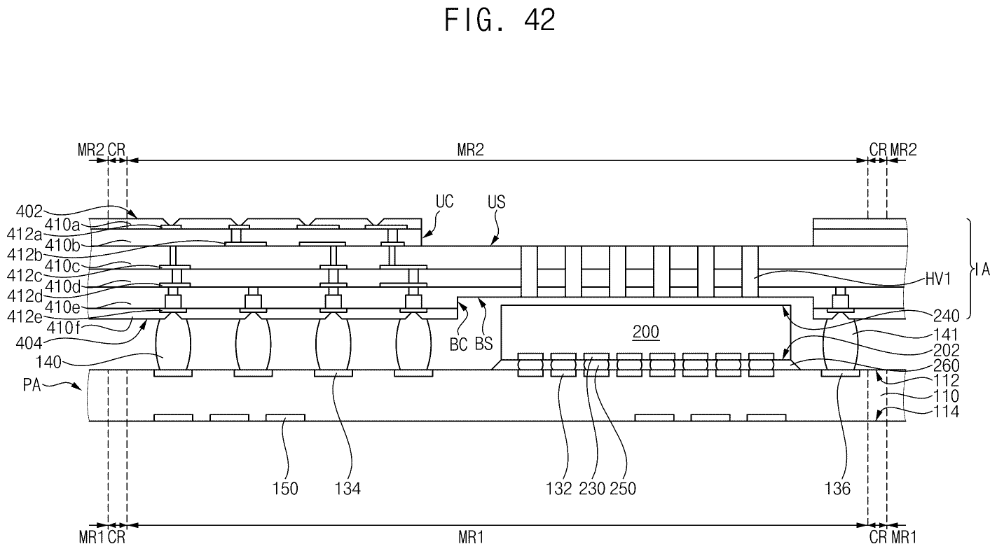

FIG. 41 is a cross-sectional view illustrating aligning an interposer array on a substrate array. FIG. 42 is a cross-sectional view illustrating mounting the interposer array onto the substrate array.

The semiconductor package manufactured by the manufacturing process illustrated in FIGS. 41 and 42 is substantially the same as the semiconductor package 105 described in FIG. 40, so identical components are denoted by the same reference numerals, and repeated descriptions of identical components are omitted.

Referring to FIG. 41, a plurality of lower connection members 140a may be positioned on a plurality of upper connection members 140b, and a plurality of lower support members 141a may be positioned on a plurality of upper support members 141b.

Specifically, the upper surface 402 of the interposer array IA may be adsorbed using a transportation apparatus, and the interposer array IA may be positioned above the substrate array PA. Then, the plurality of second mounting regions MR2 and the plurality of first mounting regions MR1 may be aligned such that the plurality of lower connection members 140a correspond to the plurality of upper connection members 140b, and the plurality of lower support members 141a correspond to the plurality of upper support members 141b.

Referring to FIG. 42, the plurality of lower connection members 140a and the plurality of upper connection members 140b may be combined to form the plurality of vertical conductive connectors 140, and the plurality of lower support members 141a and the plurality of upper support members 141b can be combined to form the plurality of support members 141 to mount the interposer array IA on the substrate array PA.

Specifically, the interposer array IA may be moved toward the substrate array PA such that the plurality of lower connection members 140a and the plurality of upper connection members 140b are in contact with each other and such that the plurality of lower support members 141a and the plurality of upper support members 141b are in contact with each other. Thereafter, a thermal compression bonding process may be performed to form the plurality of vertical conductive connectors 140 and the plurality of support members 141 by applying high temperature and pressure.

Hereinafter, a semiconductor package 106 will be described in accordance with some embodiments.

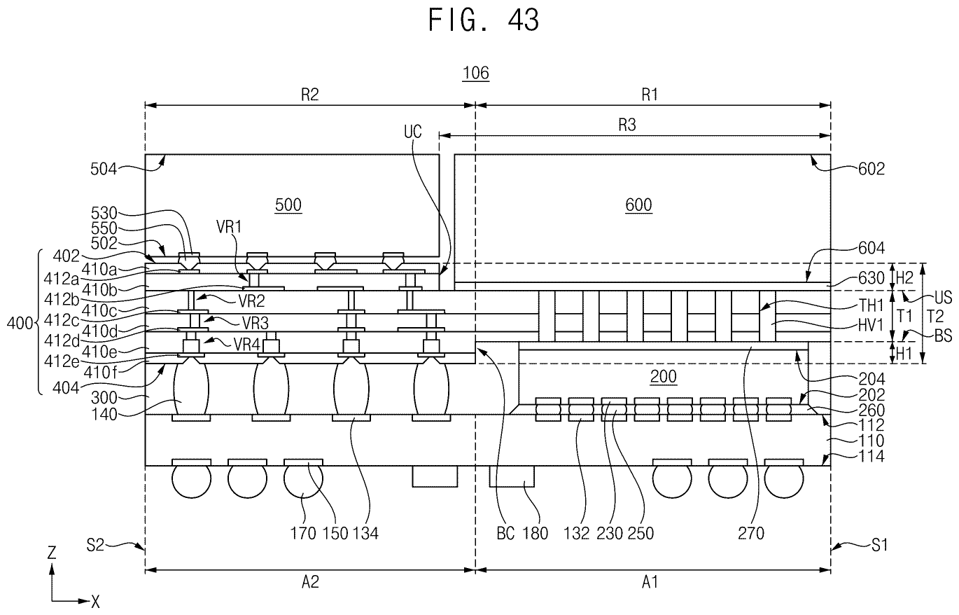

FIG. 43 is a cross-sectional view illustrating a semiconductor package in accordance with some embodiments.

Referring to FIG. 43, a semiconductor package 106 may include a package substrate 110, a first semiconductor device 200 mounted on the package substrate 110, a molding member 300 provided on the package substrate 110 to cover the first semiconductor device 200, an interposer 400 provided on the molding member 300, a second semiconductor device 500 mounted on the interposer 400, and a heat dissipation block 600 stacked on the interposer 400 to be spaced apart from the second semiconductor device 500 in a first direction (X direction).

The semiconductor package 106 illustrated in FIG. 43 is substantially identical to the semiconductor package 100 described in FIG. 1 excluding the first semiconductor device 200, so identical components are denoted by the same reference numerals and repeated descriptions of identical components are omitted.

In some embodiments, the first semiconductor device 200 may have a front surface 202 and a backside surface 204 that face each other, and the first semiconductor device 200 may be mounted on the first substrate region A1 of the package substrate 110 such that the front surface 202 faces the package substrate 110. In other words, the front surface 202 and backside surface 204 may be directly opposite of one another.

The first semiconductor device 200 may include a plurality of first chip pads 230 provided on the front surface 202, a plurality of first conductive connection members 250 provided on each of the plurality of first chip pads 230, and an underfill member 260 provided on the front surface 202 to cover the plurality of first conductive connection members 250.

Additionally, the first semiconductor device 200 may include a second thermal adhesive member 270 provided on the backside surface 204. For example, the second thermal adhesive member 270 may include the same material as the first thermal adhesive member 630 of the heat dissipation block 600. The second thermal adhesive member 270 may include a thermal interface material (TIM). The thermal interface material (TIM) may be a structure configured to effectively transfer heat between components in the semiconductor package 106 by closely fitting the components so that there are no microscopic spaces between the components.

The second thermal adhesive member 270 may be within the lower cavity BC of the interposer 400. For example, the second thermal adhesive member 270 may be provided between the backside surface 204 of the first semiconductor device 200 and the lower exposed surface BS of the lower cavity BC.

Heat generated by the first semiconductor device 200 may be transferred to the second thermal adhesive member 270, the plurality of first heat transfer vias HV1, and the heat dissipation block 600. Thus, the second thermal adhesive member may effectively transfer the heat of the first semiconductor device 200 to the heat dissipation block 600.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of some embodiments and is not to be construed as limiting thereof. Although some embodiments have been described, those skilled in the art will readily appreciate that many modifications are possible in some embodiments without materially departing from the novel teachings and advantages of the present invention. Accordingly, all such modifications are intended to be included within the scope of some embodiments as defined in the claims.

What is claimed is:

1. A semiconductor package, comprising:
a package substrate;
a first semiconductor device on the package substrate;
a plurality of vertical conductive connectors on the package substrate and electrically connected to the first semiconductor device;
an interposer on the package substrate such that the plurality of vertical conductive connectors is between the package substrate and the interposer, the interposer defining a first interposer region and a second interposer region and having a lower cavity in the first interposer region, the lower cavity having a predetermined depth from a lower surface of the interposer;
a second semiconductor device on the interposer in the second interposer region; and
a heat dissipation block on the interposer in the first interposer region,
wherein a portion of the first semiconductor device is within the lower cavity.

2. The semiconductor package of claim 1, wherein the interposer defines a third interposer region which is at least partially overlapped with the first interposer region in a plan view,
wherein the interposer has an upper cavity having a predetermined depth from an upper surface of the interposer, and
wherein a portion of the heat dissipation block is within the upper cavity.

3. The semiconductor package of claim 1, wherein the interposer includes a plurality of heat transfer vias between the first semiconductor device and the heat dissipation block.

4. The semiconductor package of claim 1, wherein the first semiconductor device has a first thermal adhesive member on the first semiconductor device and configured to connect the first semiconductor device and the interposer.

5. The semiconductor package of claim 4, wherein the first thermal adhesive member is within the lower cavity.

6. The semiconductor package of claim 4, wherein the heat dissipation block has a second thermal adhesive member on a lower surface of the heat dissipation block to connect the heat dissipation block and the interposer.

7. The semiconductor package of claim 1, wherein the first semiconductor device protrudes into the lower cavity of the interposer.

8. The semiconductor package of claim 1, wherein the interposer includes a plurality of supporting portions within the lower cavity of the interposer which contact an upper surface of the first semiconductor device.

9. The semiconductor package of claim 1, further comprising:
a molding member between the package substrate and the interposer to cover the plurality of vertical conductive connectors and the first semiconductor device.

10. The semiconductor package of claim 1, further comprising:
a plurality of supporting members on the package substrate spaced apart from the plurality of vertical conductive connectors and the first semiconductor device, the plurality of supporting members configured to support the interposer between the package substrate and the interposer.

11. A semiconductor package, comprising:
a package substrate further comprising a mounting region and a connecting region spaced apart from the mounting region along a horizontal direction;
a first semiconductor device on the mounting region of the package substrate;
a plurality of vertical conductive connectors on the connecting region of the package substrate;
an interposer on the package substrate such that the plurality of vertical conductive connectors is between the package substrate and the interposer, the interposer further comprising a first interposer region overlapped with the first semiconductor device and a second interposer region adjacent to the first interposer region;
a second semiconductor device on the second interposer region; and
a heat dissipation block on the first interposer region,
wherein the interposer includes,
a lower cavity on the first interposer region of the interposer having a predetermined depth from a lower surface of the interposer, wherein a portion of the first semiconductor device is in the lower cavity; and
an upper cavity on the first interposer region of the interposer having a predetermined depth from an upper surface of the interposer, wherein a portion of the heat dissipation block is in the upper cavity.

12. The semiconductor package of claim 11, wherein the interposer includes a plurality of heat transfer vias between the first semiconductor device and the heat dissipation block to connect the lower cavity and the upper cavity.

13. The semiconductor package of claim 11, wherein the first semiconductor device has a first thermal adhesive member on the first semiconductor device to connect the first semiconductor device and the interposer.

14. The semiconductor package of claim 13, wherein the first thermal adhesive member is within the lower cavity.

15. The semiconductor package of claim 13, wherein the heat dissipation block has a second thermal adhesive member on a lower surface of the heat dissipation block to connect the heat dissipation block and the interposer.

16. The semiconductor package of claim 11, wherein the interposer includes a plurality of supporting portions within the lower cavity of the interposer in contact with an upper surface of the first semiconductor device.

17. The semiconductor package of claim 11, further comprising:
a plurality of supporting member on the package substrate and apart from the plurality of vertical conductive connectors and the first semiconductor device, wherein the plurality of supporting members is configured to support the interposer between the package substrate and the interposer.

18. The semiconductor package of claim 11, wherein the first semiconductor device protrudes into the lower cavity of the interposer.

19. The semiconductor package of claim 11, further comprising:
a molding member between the package substrate and the interposer to cover the plurality of vertical conductive connectors and the first semiconductor device.

20. A semiconductor package, comprising:
a package substrate further comprising a mounting region and a connecting region spaced apart from the mounting region along a horizontal direction;
a first semiconductor device on the mounting region of the package substrate;
a plurality of vertical conductive connectors on the connecting region of the package substrate;
an interposer on the package substrate such that the plurality of vertical conductive connectors is between the package substrate and the interposer, the interposer further comprising a first interposer region overlapped with the first semiconductor device and a second interposer region adjacent to the first interposer region;
a molding member between the package substrate and the interposer to cover the plurality of vertical conductive connectors and the first semiconductor device;
a second semiconductor device on the second interposer region; and
a heat dissipation block on the first interposer region,
wherein the interposer includes,
a lower cavity on the first interposer region of the interposer having a predetermined depth from a lower surface of the interposer, wherein a portion of the first semiconductor device is in the lower cavity; and
an upper cavity on the first interposer region of the interposer having a predetermined depth from an upper surface of the interposer, wherein a portion of the heat dissipation block is in the upper cavity.
